(19) United States
(12) Patent Application Publication
(10) Pub. No.: US 2011/0227878 A1
(43) Pub. Date: Sep. 22, 2011

(54) SEMICONDUCTOR DEVICE, METHOD FOR MANUFACTURING SAME, AND DISPLAY DEVICE USING SEMICONDUCTOR DEVICE

(75) Inventor: Naoki Makita, Osaka (JP)

(73) Assignee: SHARP KABUSHIKI KAISHA, Osaka (JP)

(21) Appl. No.: 13/130,027

(22) PCT Filed: Nov. 9, 2009
(86) PCT No.: PCT/JP2009/005936

§ 371 Date: May 18, 2011

(30) Foreign Application Priority Data
Nov. 20, 2008 (JP) 2008-297298

(51) Int. Cl. G06F 3/042; H01L 29/786; H01L 21/336; G09G 5/10

(52) U.S. Cl. 345/175; 257/66; 438/166; 345/690; 257/E29.273; 257/E21.411

(57) ABSTRACT

In a semiconductor device having a thin film transistor and a thin film diode on a single substrate, the characteristics required for each of the devices can be obtained. The semiconductor device includes: a thin film transistor supported by a substrate 101 and having a first crystalline semiconductor layer 107 including a channel region 115 and source and drain regions 113, a gate insulating film 108 disposed to cover the first crystalline semiconductor layer 107, and a gate electrode 109 disposed on the gate insulating film 108 to control the conductivity of the channel region 115; and a thin film diode supported by the substrate 101 and having a second crystalline semiconductor layer 110 including at least an n-type region 114 and a p-type region 118. The second crystalline semiconductor layer 110 is formed on the gate insulating film 108 in contact with the surface of the gate insulating film 108. The n-type region 114 or the p-type region 118 and the source and drain regions 113 include an identical impurity element.

### TECHNICAL FIELD

The present invention relates to a semiconductor device equipped with a thin film transistor (TFT) and a thin film diode (TFD), a method of manufacturing the same, and a display device using the semiconductor device.

### BACKGROUND ART

In recent years, semiconductor devices having thin film transistors (TFTs) and thin film diodes (TFDs) on a single substrate, and electronic devices including such semiconductor devices have been under development. According to a mainstream method for manufacturing such semiconductor devices, semiconductor layers for TFTs and TFDs are formed using the same crystalline semiconductor film formed on a substrate.

Device characteristics of TFTs and TFDs formed on a single substrate are significantly affected by the crystallinity of the semiconductor layers that are destined to be the active regions of the TFT and the TFD. An established method for obtaining a favorable quality crystalline semiconductor layer on a glass substrate includes irradiation of an amorphous semiconductor film with laser light for crystallization. Crystallization can also be achieved by adding a catalytic element that facilitates the crystallization to an amorphous semiconductor film, and then conducting a heat treatment on the semiconductor film. After an amorphous semiconductor film is crystallized with this method, the obtained crystalline semiconductor film may be irradiated with the laser light for further crystallization. This technique provides a higher quality semiconductor film having a crystal orientation of a higher level of regularity compared to the conventional crystalline semiconductor films that are crystallized simply by a short, low-temperature heat treatment and a laser light irradiation.

Patent Document 1 discloses an image sensor equipped with an optical sensor section that utilizes a TFD, and a driver circuit that utilizes a TFT on a single substrate. In the technology disclosed in Patent Document 1, an amorphous semiconductor film formed on a substrate is crystallized to form semiconductor layers for the TFT and the TFD.

Formation of the TFT and the TFD in a unified manner on a single substrate, as discussed above, allows size reduction of the semiconductor device, and also allows reduction in the number of parts required, leading to a significant cost advantage. Furthermore, products with new additional features, which would not be available by conventional parts combination, can be provided.

On the other hand, Patent Document 2 discloses a technology of forming a TFT of crystalline silicon (crystalline silicon TFT) and a TFD of amorphous silicon (amorphous silicon TFD) on a single substrate using the same semiconductor film (amorphous silicon film). Specifically, a catalytic element that facilitates the crystallization of amorphous silicon is added only to a region of the amorphous silicon film formed on a substrate that is destined to become an active region of the TFT. Then, heat treatment is conducted to form a silicon film in which only the portion that is destined to become an active region of the TFT is crystallized, and the region that is destined to become a TFD remains amorphous. By using such silicon films, crystalline silicon TFTs and amorphous silicon TFDs can easily be made on a single substrate.

Furthermore, Patent Document 3 discloses a technology in which an optical sensor TFT that functions as an optical sensor and a switching TFT that functions as a switching element are formed of the same semiconductor film (amorphous silicon film). In the disclosure, the sensitivity of an optical sensor is improved by making the silicon film of the channel region of the optical sensor TFT thicker than the silicon film of the source and drain regions or the silicon film of the active region of the switching TFT. Here, in order to make the thicknesses of silicon films of these TFTs different from each other, in the photolithography for formation of island-shaped amorphous silicon films, the amorphous silicon films are partially thinned with the half exposure technology using a gray tone mask. Also, by irradiating the amorphous silicon film with laser light, thinned regions of the amorphous silicon films (the regions destined to become the source and drain regions of the optical sensor TFT and the region destined to become the active region of the switching TFT) are crystallized, and the region that was not thinned (the region destined to become the channel region of the optical sensor TFT) remains amorphous.

### RELATED ART DOCUMENTS

### Patent Documents

Patent Document 1: Japanese Patent Application Laid-Open Publication No. H6-275808
Patent Document 2: Japanese Patent Application Laid-Open Publication No. H6-275807
Patent Document 3: Japanese Patent Application Laid-Open Publication No. 2005-72126

### SUMMARY OF THE INVENTION

### Problems to be Solved by the Invention

According to Patent Document 1, one crystalline semiconductor film is crystallized to form both a semiconductor layer for TFT and a semiconductor layer for TFD. The problem with this method, however, is that since required device characteristics of TFT and TFD are different because their uses are different, it is difficult to provide the required device characteristics of TFT and TFD at the same time.

On the other hand, according to Patent Document 2 and Patent Document 3, one amorphous semiconductor film is partially crystallized, and a TFT (crystalline silicon TFT) is formed out of the crystallized portion, and a TFD (amorphous silicon TFD) is formed out of the portion that is left amorphous. With this method, characteristics of the crystalline silicon TFT can be improved by controlling the conditions for crystallization. However, during the heat process in which part of amorphous silicon film is crystallized to make crystalline silicon, hydrogen included in the original amorphous silicon film is lost. As a result, an electrically superiable amorphous silicon TFD cannot be produced using the portion that remains amorphous after the heat treatment process. The reason is that in the amorphous silicon film that has just been formed, bond hands of silicon atoms are bonded with hydrogens (terminated), but during the heat treatment for crystallization, the bonding between the silicon element and hydrogen is broken and the hydrogens are lost, resulting in a poor quality amorphous silicon having a high concentration of unpaired bond hands (dangling bonds).

Furthermore, the technology disclosed in Patent Document 3 has the following problem. The method disclosed in Patent Document 3 is advantageous for achieving higher optical sensor sensitivity, because the silicon film of the optical sensor TFT can be made thicker than the silicon film of the switching TFT. However, the half exposure and half etching techniques are used to make the thicknesses of the silicon films different from one other, which makes the manufacturing process complex. Additionally, with these techniques, some particular regions are etched to make them thinner than other regions. In this case, it is very difficult to precisely control the thickness of the regions that is thinned. As a result, the thickness of the silicon film of the switching TFTs becomes significantly inconsistent, and that could compromise the quality of the device characteristics.

As described above, when a TFT and a TFD are formed on a single substrate for semiconductor devices with a conventional method, it is difficult for both the TFT and the TFD to have their own required characteristics, and consequently, high-performance semiconductor devices might not be obtainable.

The present invention was devised in consideration of the issues described above, and is aiming at providing a semiconductor device having a thin film transistor and a thin film diode on a single substrate with the thin film transistors and the thin film diodes possessing their respective required characteristics.

### Means for Solving the Problems

A semiconductor device of the present invention includes a substrate; a thin film transistor supported by the substrate and having a first crystalline semiconductor layer including a channel region, and source and drain regions, a gate insulating film disposed to cover the first crystalline semiconductor layer, and a gate electrode disposed on the gate insulating film and controlling the conductivity of said channel region; and a thin film diode supported by the substrate and having a second crystalline semiconductor layer including at least an n-type region and a p-type region, wherein the second crystalline semiconductor layer is formed on the gate insulating film in contact with a surface of the gate insulating film, and the n-type region or the p-type region and the source and drain regions contain an identical impurity element.

In a preferred embodiment, thickness “d2” of the second crystalline semiconductor layer is greater than thickness “d1” of the first crystalline semiconductor layer.

In a preferred embodiment, the thin film transistor further includes an interlayer insulating layer in contact with the top surface of the gate electrode, and the thin film diode further includes an interlayer insulating layer in contact with the top surface of the second crystalline semiconductor layer, wherein the interlayer insulating layer of the thin film transistor and the interlayer insulating layer of the thin film diode are formed of an identical insulating film.

Preferably, depth “Dd” from the top surface of the n-type region or the p-type region to the peak of the concentration profile of the identical impurity element in the n-type region or the p-type region in the direction of thickness, and depth “Dt” from the top surface of the gate insulating film to the peak of the concentration profile of the identical impurity element in the source and drain regions in the direction of thickness are substantially the same.

Preferably, thickness “d2” of the second crystalline semiconductor layer is greater than the sum of thickness “d1” of the first crystalline semiconductor layer and thickness “d3” of the gate insulating film (i.e., d1+d3).

Preferably, the concentration profile of the identical impurity element in the n-type region or the p-type region in the direction of thickness has its peak in the second crystalline semiconductor layer.

Preferably, the concentration profile of the identical impurity element in the source and drain regions in the direction of thickness has its peak between the top surface of the gate insulating film and the bottom surface of the first crystalline semiconductor layer. More preferably, the concentration profile of the identical impurity element in the source and drain regions in the direction of thickness has its peak in the first crystalline semiconductor layer.

The thickness “d3” of the gate insulating film may be the thickness of the gate insulating film over the source and drain regions of the first crystalline semiconductor layer.

The second crystalline semiconductor layer may include an intrinsic region interposed between an n-type region and a p-type region.

In a preferred embodiment, the gate electrode is formed of an identical semiconductor film of which the second crystalline semiconductor layer is formed.

The substrate may be light-transmissive, and may further include a light-shielding layer interposed between the second crystalline semiconductor layer and the substrate.

In a preferred embodiment, the light-shielding layer is formed of an identical semiconductor film of which the first crystalline semiconductor layer is formed.

The process for manufacturing a semiconductor device of the present invention includes the steps of: (a) preparing a substrate having a first crystalline semiconductor film formed thereon; (b) forming a first island-shaped semiconductor layer destined to become an active region of a thin film transistor by utilizing a portion of the first crystalline semiconductor film; (c) forming a gate insulating film over the first island-shaped semiconductor layer; (d) forming a second crystalline semiconductor film on the gate insulating film in contact with the surface of the gate insulating film; and (e) forming a second island-shaped semiconductor layer destined to become an active region of a thin film diode by utilizing a portion of the second crystalline semiconductor film.

In a preferred embodiment, the thickness of the second crystalline semiconductor film is greater than the thickness of the first crystalline semiconductor film.

In a preferred embodiment, the thickness of the second crystalline semiconductor film is greater than the combined thickness of the first crystalline semiconductor film and the gate insulating film.

In a preferred embodiment, after the aforementioned step (c), the manufacturing method further includes the step of forming a gate electrode of a thin film transistor over the gate insulating film, wherein the thickness of the second crystalline semiconductor film is greater than the combined thickness of a region of the first crystalline semiconductor film that is not covered by the gate electrode and of the gate insulating film.

After the aforementioned step (e), preferably the manufacturing method further includes the step of doping an identical impurity element simultaneously into regions of the first island-shaped semiconductor layer that are destined to become source and drain regions and regions of the second island-shaped semiconductor layer that are destined to become an n-type region or a p-type region.

After the aforementioned step (e), the manufacturing method may further include the steps of: (f) doping a first impurity element into regions of the first island-shaped semiconductor layer that are destined to become source and drain regions through the gate insulating film; (g) doping an n-type impurity element into a region of the second island-shaped semiconductor layer that is destined to become an n-type region; and (h) doping a p-type impurity element into a region of the second island-shaped semiconductor layer that is destined to become a p-type region.

The first impurity element may include an n-type impurity element, and the step (f) and the step (g) may be conducted simultaneously.

The first impurity element may include a p-type impurity element, and the step (f) and the step (h) may be conducted simultaneously.

In a preferred embodiment, the first island-shaped semiconductor layer is composed of a plurality of island-shaped semiconductor layers including an island-shaped semiconductor layer destined to become an active region of an n-channel type thin film transistor and an island-shaped semiconductor layer destined to become an active region of a p-channel type thin film transistor; the aforementioned step (f) includes the steps of: (f1) doping an n-type impurity element into, of the first island-shaped semiconductor layer, the island-shaped semiconductor layer destined to become an n-channel type thin film transistor through the gate insulating film; (f2) doping a p-type impurity element into, of said first island-shaped semiconductor layer, an island-shaped semiconductor layer that is destined to become a p-channel type thin film transistor through the gate insulating film, wherein the step (f1) is conducted simultaneously with the step (g), and the step (f2) is conducted simultaneously with the step (h).

In a preferred embodiment, after the aforementioned step (c), the manufacturing method further includes the step of forming a gate electrode of a thin film transistor on the gate insulating film, wherein the step of forming the gate electrode includes the step of pattering the second crystalline semiconductor film to form a second island-shaped semiconductor layer destined to become an active region of a thin film diode and at least a portion of the gate electrode simultaneously.

The aforementioned substrate may be a light-transmissive substrate. Additionally, before the aforementioned step (c), the manufacturing method may further include the step of forming a light-shielding layer on a bottom of a region of the substrate on which a second island-shaped semiconductor layer destined to become an active region of a thin film diode is to be formed, for blocking the light entering from the opposite surface of the substrate.

In a preferred embodiment, the aforementioned step (b) includes the step of pattering the first crystalline semiconductor film to form a first island-shaped semiconductor layer destined to become an active region of a thin film transistor and at least a portion of the light-shielding layer simultaneously.

The aforementioned step (a) may include the steps of: (a1) preparing a substrate having an amorphous semiconductor film formed thereon; and (a2) forming a first crystalline semiconductor film by irradiating the amorphous semiconductor film with laser light to crystallize the amorphous semiconductor film.

The aforementioned step (a) may include the steps of: (a1) preparing a substrate having an amorphous semiconductor film formed thereon; (a2) adding a catalytic element that facilitates crystallization to the amorphous semiconductor film; and (a3) forming a second crystalline semiconductor film by conducting a heat treatment on the amorphous semiconductor film to which the catalytic element has been added to crystallize the amorphous semiconductor film.

The aforementioned step (d) may also be the step of depositing a second crystalline semiconductor film on the gate insulating film with a plasma CVD method.

Other semiconductor devices of the present invention are semiconductor devices manufactured with any one of the manufacturing methods described above.

A display device of the present invention is a display device equipped with a display region having a plurality of display sections, a frame region located in the periphery of the display region, and an optical sensor section having a thin film diode, wherein each of the display sections has an electrode and a thin film transistor connected to the electrode, the thin film transistor and the thin film diode are formed on a single substrate; the thin film transistor includes a first crystalline semiconductor layer including a channel region, source and drain regions, a gate insulating film disposed to cover the first crystalline semiconductor layer, and a gate electrode disposed on the gate insulating film and controlling the conductivity of the channel region; the thin film diode includes a second crystalline semiconductor layer including at least an n-type region and a p-type region; the second crystalline semiconductor layer is formed on the gate insulating film in contact with the surface of the gate insulating film; and the n-type region or the p-type region and the source and drain regions contain an identical impurity element.

In a preferred embodiment, the display section further includes a backlight and a backlight control circuit that adjusts the luminance of the light projected from the backlight; and the optical sensor section generates illuminance signals based on brightness of ambient light and outputs the signals to the backlight control circuit.

In a preferred embodiment, a display device has a plurality of photo touch sensor sections each having the optical sensor section, wherein the plurality of photo touch sensor sections are disposed in the display region such that each one of the photo touch sensor sections corresponds to one display section or a set of two or more display sections.

### Effects of the Invention

According to the present invention, in the semiconductor device having a TFT and a TFD on a single substrate, semiconductor layers for the TFT and the TFD are formed of different semiconductor films. As a result, the semiconductor layers can be optimized to provide device characteristics required for each of the devices. That is, both the device characteristics required for the TFT and the device characteristics required for the TFD can be obtained.

According to the method of manufacturing of the present invention, a high performance semiconductor device equipped with TFTs and TFDs can easily be manufactured without increasing the manufacturing steps or manufacturing cost. The product size reduction, performance enhancement, and cost reduction can also be achieved.

In particular, because a second crystalline semiconductor layer destined to become an active layer for a TFD can be formed after a first crystalline semiconductor layer destined to be an active layer for a TFT is formed, the thickness and crystallinity of each of the crystalline semiconductor layers can be optimized individually to achieve the characteristics respectively required for the TFT and the TFD. Also, the number of the manufacturing steps can further be reduced if the semiconductor layers for the TFT and the TFD are subjected to doping simultaneously.

The present invention can suitably be applied to a liquid crystal display device having a sensor feature. It is advantageous to apply the present invention to, for example, a display device equipped with TFTs to be used for a driver circuit, TFTs to be used for switching the pixel electrodes, and TFDs utilized as an optical sensor, because a TFT having high field effect mobility and a low threshold voltage and a TFD having a low dark current and a high light S/N ratio (the ratio of the current under the light to the current in the darkness) can be formed on a single substrate. In particular, by independently optimizing the semiconductor layer for the channel region, which substantially determines the field effect mobility of the TFT, and the semiconductor layer for the intrinsic region, which significantly affects the light sensitivity of the TFD, the optimum device characteristics of each of the semiconductor devices can be obtained.

### BRIEF DESCRIPTION OF THE DRAWINGS

FIG. 1(a) is a schematic cross-sectional view of a semiconductor device according to an embodiment of the present invention, and FIG. 1(b) is a cross-sectional view that illustrates the concentration profile of an impurity element in the semiconductor layers for a TFT and a TFD.

FIG. 2 is a schematic cross-sectional view of a semiconductor device according to Embodiment 1 of the present invention.

FIGS. 3(A) through 3(E) are schematic cross-sectional views illustrating the manufacturing steps for a semiconductor device according to Embodiment 1 of the present invention.

FIGS. 4(F) through 4(H) are schematic cross-sectional views illustrating the manufacturing steps for a semiconductor device according to Embodiment 1 of the present invention.

FIGS. 5(A) through 5(F) are schematic cross-sectional views illustrating the manufacturing steps for a semiconductor device according to Embodiment 2 of the present invention.

FIGS. 6(G) through 6(J) are schematic cross-sectional views illustrating the manufacturing steps for a semiconductor device according to Embodiment 2 of the present invention.

FIGS. 7(A) through 7(F) are schematic cross-sectional views illustrating the manufacturing steps for a semiconductor device according to Embodiment 3 of the present invention.

FIGS. 8(G) through 8(K) are schematic cross-sectional views illustrating the manufacturing steps for a semiconductor device according to Embodiment 3 of the present invention.

FIGS. 9(A) through 9(E) are schematic cross-sectional views illustrating the manufacturing steps for a semiconductor device according to Embodiment 4 of the present invention.

FIGS. 10(F) through 10(H) are schematic cross-sectional views illustrating the manufacturing steps for a semiconductor device according to Embodiment 4 of the present invention.

FIGS. 11(I) through 11(K) are schematic cross-sectional views illustrating the manufacturing steps for a semiconductor device according to Embodiment 4 of the present invention.

FIG. 12 is a circuit diagram of an optical sensor TFD according to Embodiment 5 of the present invention.

FIG. 13 is a configuration diagram of an optical sensor type touchscreen according to Embodiment 5 of the present invention.

FIG. 14 is a schematic plan view that illustrates a rear substrate of a touchscreen type liquid crystal display device according to Embodiment 5 of the present invention.

FIG. 15 is a perspective view illustrating a liquid crystal display device equipped with an ambient light sensor according to Embodiment 5 of the present invention.

### DETAILED DESCRIPTION OF EMBODIMENTS

A semiconductor device of the present invention includes a thin film transistor formed of a first crystalline semiconductor layer and a thin film diode formed of a second crystalline semiconductor layer on a single substrate. The second crystalline semiconductor layer is formed in contact with the surface of a gate insulating film. An n-type region or a p-type region of the thin film diode and source and drain regions of the thin film transistor have an identical impurity element.

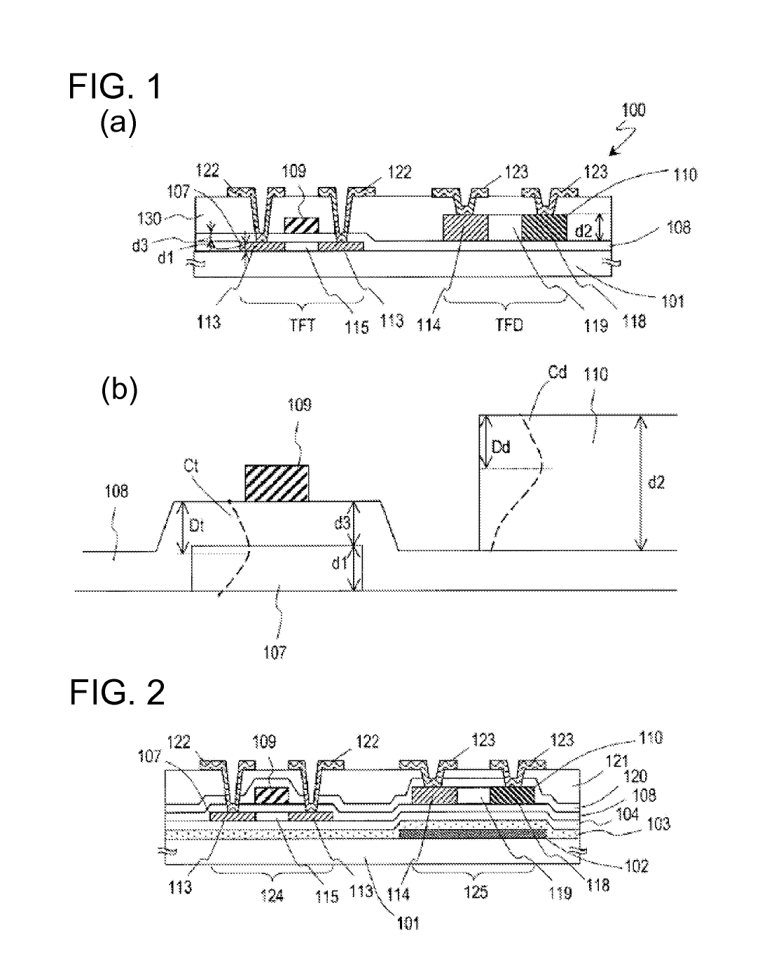

Configurations of semiconductor devices of the present invention are described in detail with reference to figures below. FIG. 1(a) is a schematic cross-sectional view of a semiconductor device according to a preferred embodiment of the present invention. A semiconductor device 100 includes a substrate 101, and a thin film transistor (TFT) and a thin film diode (TFD) that are supported by the substrate 101. The TFT in this embodiment has a semiconductor layer 107, which includes a channel region 115 and source and drain regions 113; a gate insulating film 108 disposed to cover the semiconductor layer 107; and a gate electrode 109 that is disposed on the gate insulating film 108 and controls the conductivity of a channel region 115. Semiconductor layer 107 is a crystalline semiconductor layer. The TFD in this embodiment has a semiconductor layer 110 that includes an intrinsic region 119, an n-type region 114, and a p-type region 118. The semiconductor layer 110 is a crystalline semiconductor layer, and is formed on the gate insulating film 108 in contact with the top surface of the gate insulating film 108.

The n-type region 114 or the p-type region 118 and the source and drain regions 113 have the same impurity element. That is, if the TFT is a channel-type TFT, the source and drain regions 113 and the n-type region 114 of the TFD contain the same n-type impurity element. If the TFT is a p-channel type TFT, the source and drain regions 113 and the p-type region 118 contain the same impurity element. The semiconductor layer 110 needs to have at least an n-type region 114 and a p-type region 118, but does not have to have an intrinsic region 119.

In this embodiment, an interlayer insulting layer 130 is formed in contact with the top surface of the gate electrode 109 of the TFT and in contact with the top surface of the semiconductor layer 110 of the TFD. This structure in which the interlayer insulating layers of the TFT and the TFD are made of the same insulating film is preferable, because it allows a simplified manufacturing process.

For the semiconductor device 100, the semiconductor layer 107 for the TFT and the semiconductor layer 110 for the TFD are separate layers formed of different crystalline semiconductor films. Therefore, most suitable characteristics for each of the devices can individually be obtained. More specifically, by optimizing the quality, thickness, and crystalline state and the like for the semiconductor layers 107 and 110, required device characteristics for each of the elements can be obtained.

In particular, for TFTs used for driver circuits, a high field effect mobility and a low threshold voltage are required in order to obtain a high current drive capability. Utilizing the crystalline semiconductor layer 107 as an active layer, as in this embodiment, is advantageous because it provides a high field effect mobility and a low threshold voltage. Also, regardless of the characteristics required in the semiconductor layer 110, formation method for semiconductor layer 107, crystalline state, and thickness and the like can be selected flexibly to obtain desired field effect mobility and a desired threshold voltage.

Furthermore, for switching TFTs that switch the pixel electrodes, the leakage current at the time of the OFF operation of the TFT has to be suppressed and a high on/off ratio is required. Setting the thickness of the semiconductor layer 107 small is effective for satisfying these requirements. Thinning the semiconductor layer 107 can improve the S value of the TFT characteristics (current rising characteristics when a subthreshold voltage is applied), and it is also effective against the lowering of the threshold voltage. On the other hand, excessive thinning of the semiconductor layer 107 lowers the current during the ON operation. Therefore, the suitable thickness range of the semiconductor layer 107 is 30 nm or more and 60 nm or less.

For TFDs, on the other hand, if they are used for optical sensors, for example, the preferable crystalline state and thickness of the semiconductor layer 110 are different from the crystalline state and thickness of the semiconductor layer 107 for the TFT. When a TFD is used as an optical sensor, the TFD is reverse-biased to be turned off to detect the leakage current increase/decrease at the time of light exposure. The light sensitivity in this case improves as the thickness of the semiconductor layer 110 increases. That is, an increased thickness of the semiconductor layer 110 for the TFD contradicts with a preferable thickness of the semiconductor layer 107 for TFT. Also, a high quality crystallinity as required for the semiconductor layer 107 for TFT is not required for the semiconductor layer 110 for the TFD, but considering the signal reset speed under forward biased operation and detection sensitivity in the infrared region, the semiconductor layer 110 is preferably crystalline rather than amorphous. Therefore, for the semiconductor layer 110 for the TFD, it is advantageous to use a crystalline semiconductor layer that is different from the semiconductor layer 107 for the TFT, and to make its thickness greater than the thickness of the semiconductor layer 107 for the TFT.

In this embodiment, an n-type region 114 or a p-type region 118 and source and drain regions 113 are preferably formed in a single doping process. In this way, semiconductor device having a TFT and a TFD as described above can be obtained on a single substrate 101 in a simpler manner, which provides simplified device structures.

The semiconductor device 100 according to this embodiment has following advantages over semiconductor devices of the aforementioned Patent Documents 2 and 3.

According to the disclosure of Patent Document 2, part of a single amorphous semiconductor film is crystallized to form a semiconductor layer for the TFT, and the portion that is left amorphous is used to form a semiconductor layer for the TFD. With this method, as described above, it is difficult to obtain a TFD having sufficient characteristics required for an optical sensor. The reason is that, during the heat treatment process that converts part of the amorphous silicon film into crystalline silicon, hydrogens included in the original amorphous silicon film are lost.

After an amorphous silicon film is formed, hydrogen atoms acquired when the film is formed bind with the dangling bonds of Si atom to form Si—H bonding, which inactivates the Si dangling bonds in the amorphous silicon film. When a heat treatment is conducted to crystallize part of the amorphous silicon film, Si—H bonding is broken, activating the Si dangling bonds. Since the Si-H binding energy is about 400° C., heat treatment of 400° C. or higher temperature breaks the bonds, releasing the hydrogens. Si dangling bonds that have lost the hydrogen bonding provides deep traps for the electrons and holes, thereby significantly degrading the device characteristics of the TFT and the TFD. In particular, in the case of an optical sensor, this significantly deteriorates the current in a dark environment (dark current), which raises the base. Additionally, the current under light exposure (light current) also decreases. Consequently, the light/dark ratio (i.e., light current/dark current), an indicator of the performance of the optical sensor, further deteriorates, and therefore, a working optical sensor cannot be provided.

According to the disclosure of Patent Document 2, hydrogen is supplied to the semiconductor layer for the TFD and the TFT after the crystallization process, thereby forming Si—H bonding again to inactivate the Si dangling bonds. However, the semiconductor layer for the TFD, which is an amorphous silicon layer, contains a large number of dangling bonds, which is beyond the comparison with the crystalline silicon layer. This makes it extremely difficult for the semiconductor layer for the TFD to restore the original good condition that existed right after the formation.

According to the disclosure of Patent Document 3, half exposure and half etching are conducted on a single amorphous silicon film to thin part of the amorphous silicon film, which makes the film thicknesses of the semiconductor layer for the TFT and the semiconductor layer for the TFD different. However, this etching is extremely difficult to control, and can cause inconsistent thickness of the thinned region, i.e. the thickness of the semiconductor layer for the TFT. The inconsistent thickness of the semiconductor layer for TFT significantly affects the TFT characteristics. Also, the thinned region, i.e. the surface of the semiconductor layer for the TFT, is exposed to the etching and consequently suffers an etching damage, which adversely affects the TFT characteristics and reliability.

Next, only the thinned region is crystallized by being irradiated with laser light to form a silicon layer for a switching TFT. On the other hand, a thick portion of the amorphous silicon film (the portion that was not thinned) remains amorphous and this portion will become a silicon layer of an optical sensor TFT. This method, however, requires irradiation energy high enough to melt the thinned region of amorphous silicon film when the region is crystallized by the laser light. Therefore, during this crystallization process, hydrogens are disengaged in the thick portion of the amorphous silicon film due to the irradiation energy. Furthermore, when such high irradiation energy is used, disengagement of hydrogens could cause the film chipping. To prevent the film chipping, the amorphous silicon film must be heat treated for hydrogen removal prior to the laser irradiation, or the amorphous silicon film must be formed at a temperature of 400° C. or higher. As just described, it is difficult to form an amorphous silicon layer of a favorable condition as an active layer of the optical sensor TFT.

In contrast, in this embodiment, a semiconductor layer 107 for the TFTs and a semiconductor layer 110 for the TFD are formed of different layers of semiconductor film. As a result, the thicknesses and the crystalline states of the semiconductor layers 107 and 110 can be optimized independently, thereby avoiding the inconsistency in the film thickness and occurrence of damages due to etching.

In this embodiment, a crystalline semiconductor layer is used for the semiconductor layer 110 for the TFD as well. When a TFD is used as an optical sensor, and the semiconductor layer 110 for the TFD is a crystalline semiconductor layer, the TFD is less sensitive within the visible light range, but more sensitive in the infrared region, compared to a TFD utilizing an amorphous semiconductor layer. When a TFD is used for forward-bias operation such as the reset operation, a crystalline semiconductor layer, which has a higher mobility than the amorphous semiconductor layer, is preferably used because using a crystalline semiconductor layer improves the signal reset speed, and because using an amorphous semiconductor layer presents the aforementioned manufacturing issues.

From the perspective of the simplification of manufacturing process, it is not desirable to use different layers to form a semiconductor layer 107 for the TFT and a semiconductor layer 110 for the TFD respectively. However, the method disclosed in Patent Document 3 requires an extra etching process to thin a portion of the silicon film. Therefore, compared to the method disclosed in Patent Document 3, the present embodiment has just one additional process, i.e. the second semiconductor film formation. Also, in the method of Patent Document 3, as described above, the precision of the aforementioned etching determines the thickness of the thinned portion of the silicon film, resulting in significantly inconsistent silicon film thicknesses. On the other hand, in this embodiment, the thicknesses of the semiconductor film for the TFT and the semiconductor film for the TFD can be appropriately selected in their own formation processes. Consequently, the thickness of each of the semiconductor films can be controlled in a simpler manner, and the thicknesses of each of the semiconductor films can be significantly less variable. In this embodiment, the thickness of the semiconductor film for the TFT determines the thickness “d1” of the semiconductor layer 107 for the TFT and the thickness of semiconductor film for the TFD determines the thickness “d2” of the semiconductor layer 110 for the TFD.

In this embodiment, as described above, the thickness “d1” of the semiconductor layer 107 for the TFT and the thickness “d2” of the semiconductor layer 110 for the TFD can be set independently. The thickness “d2” of the semiconductor layer 110 for the TFD is preferably set greater than the thickness “d1” of the semiconductor layer 107 for the TFT. For TFTs, this structure improves the on/off ratio and lowers the threshold voltage, leading to an enhanced TFT performance. For the TFD, this structure increases the light current, which determines the optical sensor sensitivity, and improves the optical sensor performance.

Furthermore, in particular when the TFD is used as an optical sensor, the TFD performance can further be improved and the manufacturing process can be more simplified if the thickness “d2” of the semiconductor layer 110 for the TFD is set greater than the sum of the thickness “d1” of semiconductor layer 107 for the TFT and the thickness “d3” of the gate insulating film 108 (d1+d3), that is, d2>d1+d3. The reason is described below.

When source and drain regions 113 of the semiconductor layer 107 for the TFT (the first crystalline semiconductor layer) and an n-type region 114 or a p-type region 118 of the semiconductor layer 110 for the TFD (the second crystalline semiconductor layer) are doped with dopants simultaneously, the semiconductor layer 107 for the TFT is “through-doped,” i.e., doped through a gate insulating film 108, and the semiconductor layer 110 for the TFD is “bare-doped,” by which the dopants are directly implanted. During the implantation, the semiconductor layer 107 for the TFT and the semiconductor layer 110 for the TFD, which are both crystalline, suffer an implantation damage, and the crystalline structure is significantly destructed. Although the heat treatment is conducted later to restore the crystallinity and to activate the dopant, if the crystals are excessively destructured, the crystallinity cannot be restored by the heat treatment performed later. As a result, source and drain regions 113 of TFT and an n-type region 114 or a p-type region 118 of TFD become highly resistive, which could negatively affect the device characteristics. In particular, although dopant is implanted into the semiconductor layer 107 for the TFT by the through-doping, through the gate insulating film 108, the dopant is implanted into the semiconductor layer 110 for TFD directly by the bare-doping. Therefore, the semiconductor layer 110 suffers more severe implantation damage. Additionally, the doping process must be conducted under conditions optimized for the semiconductor layer 107 for the TFT. Under such conditions, crystals in the semiconductor layer 110 for the TFD may be destructured so severely that the crystalline structure cannot be restored by the heat treatment performed later. As a result, the n-type region 114 or the p-type region 118 may become highly resistive.

By setting the thicknesses of the semiconductor layer 107, the semiconductor layer 110, and the gate insulating film 108 such that the aforementioned relationship, d2>d1+d3, is satisfied, excessive crystal destruction in the semiconductor layer 110 for the TFD, which could occur as an implantation damage, can be prevented even if the implantation is conducted under the optimal condition for the semiconductor layer 107 for the TFT. Consequently, the n-type region 114 or the p-type region 118 can be made low resistive.

Detailed description is provided below with reference to FIG. 1(b). FIG. 1(b) is a schematic cross-sectional view that illustrates an example of the concentration profile of the impurity doped into the semiconductor layers 107 and 110 of this embodiment in the direction of thickness.

In the example illustrated, an n-type or p-type impurity element is doped into the semiconductor layer 107 for TFT through the thickness “d3” of the gate insulating film 108 (through-doping). On the other hand, the impurity element is doped into the semiconductor layer 110 for TFD directly, i.e. not through the gate insulating film 108 (bare-doping).

The impurity element concentration profile in the gate insulating film 108 and the semiconductor layer 107 in the direction of the depth from the top surface of the gate insulating film 108 is indicated by a curve “Ct.” On the other hand, the impurity element concentration profile in the semiconductor layer 110 from the top surface of the semiconductor layer 110 in the direction of depth is indicated by a curve “Cd.” As shown in FIG. 1(b), when an impurity element is doped into the semiconductor layers 107 and 110 in the same doping step, the concentration profiles “Ct” and “Cd” are about the same. Therefore, depth “Dt” from the top surface of the gate insulating film 108 to the peak of the concentration profile “Ct” and depth “Dd” from the top surface of the semiconductor layer 110 to the peak of the concentration profile “Cd” are about the same (Dt≈Dd).

The doping conditions for the semiconductor layer 110 for the TFD are preferably set such that the peak depth “Dd” is smaller than the thickness “d2” of the semiconductor layer 110 (i.e., Dd<d2). That is, the doping conditions are preferably set such that the concentration profile “Cd” has its peak in the semiconductor layer 110. “The concentration profile has its peak in a semiconductor layer” means that the peak of the concentration profile of a semiconductor layer in the direction of thickness is located between the top surface and the bottom surface of the semiconductor layer. This does not include the case where the concentration reaches its peak at the top surface or at the bottom surface of the semiconductor layer.

Since the peak depth “Dd” is located above the bottom surface of the semiconductor layer 110 for the TFD, the impurity concentration at the bottom surface can be kept lower than the peak concentration. That is, at the bottom surface of the semiconductor layer 110, excessive crystal destruction can be prevented. Therefore, by the post-doping heat treatment, crystal restoration occurs from the bottom surface of the semiconductor layer 110, where crystalline state is maintained, towards the top surface of the semiconductor layer 110. As a result, the n-type region 114 or the p-type region 118 of the TFD can be made low resistive, and therefore an optical sensor TFD having a high light/darkness ratio can be obtained. On the contrary, if the peak depth “Dd” is greater than the thickness “d2” of the semiconductor layer 110 (Dd>d2), the crystallinity of the semiconductor layer 110 is destructured by the doping throughout the thickness, and a starting point for crystallinity restoration will be lost. That is, post-doping heat treatment cannot fully restore the crystalline state. As a result, the n-type region 114 or the p-type region 118 of TFD becomes highly resistive, and desired device performance cannot be obtained.

On the other hand, the doping conditions for the semiconductor layer 107 for TFT are preferably set such that the peak depth “Dt” is smaller than the sum of the thickness “d1” of the semiconductor layer 107 and the thickness “d3” of the gate insulating film 108 (i.e., Dt<(d1+d3)). That is, the concentration profile “Ct” preferably has its peak between the top surface of the gate insulating film 108 and the bottom surface of the semiconductor layer. With this setting, the peak depth “Dt” is located above the bottom surface of the semiconductor layer 107 for the TFT, which makes it possible to suppress the impurity concentration at the bottom surface to a value lower than the peak concentration, thereby preventing excessive crystal destruction in the semiconductor layer 107 at its bottom surface. This allows the post-doping heat treatment to restore the crystallinity from the bottom surface of the semiconductor layer 107 where the crystalline state is maintained. As a result, the source and drain regions 113 of the TFT can be made to be low resistive, which reduces the ON resistance of the TFT. On the contrary, if the peak depth “Dt” is greater than the sum of thickness “d1” of the semiconductor layer 107 and thickness “d3” of the gate insulating film 108 (Dt>(d1+d3)), crystallinity of the semiconductor layer 107 is destructured throughout the thickness, and a starting point for crystallinity restoration will be lost. In this case, the post-doping heat treatment cannot fully restore the crystalline state. As a result, the source and drain regions 113 of the TFT become highly resistive, and the desired device performance cannot be obtained.

It is more advantageous if the doping conditions are set such that peak depth “Dt” satisfy the relationship d3<Dt<d1+d3. In addition to the effects described above, this condition allows the concentration profile “Ct” to have a peak in the semiconductor layer 107. Consequently, the impurity concentration of the source and drain regions of the TFT can be made even higher, thereby further reducing the TFT ON resistance.

If doping conditions for the semiconductor layer 107 for the TFT are set such that a relationship Dt<d1+d3 is satisfied, because the peak depth “Dt” of the concentration profile “Ct” and the peak depth “Dd” of the concentration profile “Cd” are about the same (i.e., Dt≈Dd), the relationship Dd<d1+d3 is satisfied. If the thickness “d2” of the semiconductor layer 110 is greater than d1+d3, the peak depth “Dd” always satisfies the relationship Dd<d2 (i.e., Dd<d1+d3<d2).

If, as described above, the thicknesses of the layers 107, 108, and 110 satisfy the relationship d1+d3<d2, the impurity will not be implanted relatively deep into the thickness “d2” of the semiconductor layer 110 (the second crystalline semiconductor layer) for the TFD even if the doping condition (peak depth “Dt”) for the semiconductor layer 107 (the first crystalline semiconductor layer) for the TFT is optimized to make source and drain regions low resistive. Consequently, the crystallinity destruction due to the implantation damage can be suppressed at the bottom surface of the semiconductor layer 110 (surface boundary between the semiconductor layer 110 and the gate insulating film 108), thereby enabling the heat treatment to be performed later to lower the resistance of the n-type region 114 or p-type region 118 of the TFD. In this way, by utilizing the thickness “d3” of the gate insulating film, the doping conditions required for the semiconductor layer 107 and the doping conditions required for the semiconductor layer 110 can both be realized.

When the thickness of the gate insulating film 108 is not uniform throughout the substrate 101, the thickness “d3” of the gate insulating film 108 refers to the thickness of the portion of the gate insulation film 108 located above the source and drain regions 113 of the semiconductor layer 107.

In this embodiment, the gate electrode 109 may be formed of the same crystalline semiconductor film of which the semiconductor layer 110 for the TFD is formed. With this configuration, the manufacturing process can be simplified.

In this embodiment, a light-transmissive substrate (glass substrate and the like) may be used as the substrate 101. In this case, a light-shielding layer (not shown) may further be provided between the semiconductor layer 110 for the TFD and the substrate 101.

When a TFD is utilized as an optical sensor, the semiconductor layer 110, which is destined to become the active layer, must respond only to external light. However, when this embodiment is applied to a transmissive liquid crystal display device, for example, a light-shielding layer is preferably provided on the side of the backlight, which is generally provided behind an active matrix substrate (here, substrate 101), so that the TFD does not detect the light from the backlight. The light-shielding layer is disposed at an appropriate location to shield the semiconductor layer 110 that will become the active region of the TFD from the light. Typically, the light-shielding layer is interposed between the semiconductor layer 110 and the substrate 101 in such manner as to overlap at least a portion of the semiconductor layer 110. The entirety or a portion of the light-shielding layer is preferably formed of the same film of which the semiconductor layer for the TFT is formed. With this configuration, the manufacturing process can further be simplified.

Next, a method of manufacturing a semiconductor device of this embodiment is described.

The manufacturing method of this embodiment includes the steps of: preparing a substrate having a first crystalline semiconductor film formed thereon; forming a first island-shaped semiconductor layer destined to become the active region of a thin film transistor by utilizing a portion of the first crystalline semiconductor film; forming a gate insulating film over the first island-shaped semiconductor layer; forming a second crystalline semiconductor film (amorphous semiconductor film for a TFD) over the gate insulating film; and forming a second island-shaped semiconductor layer destined to become the active region of a thin film diode by utilizing a portion of the second crystalline semiconductor film for the TFD.

Preferably, the second crystalline semiconductor film for the TFD is formed to have a thickness greater than the thickness of the first crystalline semiconductor film. More preferably, the thickness of the second crystalline semiconductor film for the TFD is set to be greater than the sum of the thickness of the first crystalline semiconductor film and the thickness of the gate insulating film. Yet more preferably, the thickness of the second crystalline semiconductor film for the TFD is set to be greater than the sum of the thickness of a region of the first crystalline semiconductor film that is not covered by a gate electrode formed on the gate insulating film and the thickness of the gate insulating film.

By setting the thicknesses of the first crystalline semiconductor film and the second amorphous semiconductor film for the TFD as described above, optimum conditions required respectively for the semiconductor layer for the TFT and the semiconductor layer for the TFD, particularly for the channel region of the TFT and the intrinsic region of the TFD, can separately be provided. For example, by applying this embodiment to a display device equipped with an optical sensor, TFTs for the driver circuit, i.e., TFTs used in the driver circuit, can have a high field effect mobility and a low threshold voltage, and therefore can present an enhanced driving capability; and a TFT for switching, which functions as a switching element in each of the pixels, can have better switching characteristics. Also, the TFD can have a low dark current and high photo currents, and therefore can present superior characteristics as an optical sensor, that is, a high light to dark ratio (S/N ratio). Furthermore, according to this embodiment, these two kinds of semiconductor devices can be made on a single substrate without significantly increasing the number of the manufacturing steps and at a low manufacturing cost. Also, because a TFT and a TFD are made on a substrate, compared to the case where, for example, a TFD is mounted after a TFT is formed on the substrate, the size of the semiconductor devices (area and thickness) can significantly be reduced.

The manufacturing method according to this embodiment includes, after the first and second island-shaped semiconductor layers are formed, the steps of: doping an impurity element through a gate insulating film (through-doping) into regions destined to become source and drain regions of the first island-shaped semiconductor layer; doping n-type impurity element directly (bare-doping) into a region destined to become an n-type region of the second island-shaped semiconductor layer; and doping a p-type impurity element directly (bare-doping) into a region destined to become a p-type region of the second island-shaped semiconductor layer.

With this method, n-type or p-type impurity regions that are destined to become source and drain regions are formed in the semiconductor layer for the TFT, and an n-type impurity region and a p-type impurity region can be formed in the semiconductor layer for the TFD. Accordingly, each of the devices can be completed on a single substrate.

If the impurity element doped into regions destined to be source and drain regions of the first island-shaped semiconductor layer is an n-type impurity element, the above-mentioned through-doping is preferably conducted simultaneously with the bare-doping of the n-type impurity element into a region destined to become an n-type region of the second island-shaped semiconductor layer. Conducting the doping for forming the source and drain regions of an n-channel type TFT and the doping for forming an n-type impurity region of a TFD in a single step as described above can further simply the manufacturing process.

If the impurity element doped into regions destined to become source and drain regions of the first island-shaped semiconductor layer is a p-type impurity element, the above-mentioned through-doping is preferably conducted simultaneously with the doping of a p-type impurity element into a region destined to become a p-type region of the second island-shaped semiconductor layer. Conducting the doping for forming the source and drain regions of an p-channel type TFT and the doping for forming an p-type impurity region of a TFD in a single step as described above can further simply the manufacturing process.

In this embodiment, a plurality of first island-shaped semiconductor layers that includes the first island-shaped semiconductor layer that will become an active region of an n-channel type thin film transistor and the first island-shaped semiconductor layer that will become an active region of a p-channel type thin film transistor may be formed on a single substrate. In this case, an n-type impurity element is doped into the first island-shaped semiconductor, which is destined to become an n-channel type thin film transistor, and a p-type impurity element is doped into the first island-shaped semiconductor layer, which is destined to become a p-channel type thin film transistor. Among these processes, the through-doping of an n-type impurity element into the source and drain regions of the first island-shaped semiconductor layer, which is destined to become an n-channel type thin film transistor, is preferably conducted simultaneously with the bare-doping of an n-type impurity element into a region destined to become an n-type region of the second island-shaped semiconductor layer. Similarly, the through-doping of an p-type impurity element into the source and drain regions of the first island-shaped semiconductor layer destined to become a p-channel type thin film transistor is preferably conducted simultaneously with the bare-doping of a p-type impurity element into a region destined to become a p-type region of the second island-shaped semiconductor layer.

When forming a TFT circuit with a CMOS structure, this manufacturing method allows the doping for forming source and drain regions of the n-channel type TFT and the doping for forming an n-type impurity region of a TFD to be conducted in a single step, and allows the doping for forming source and drain regions of the p-channel type TFT and the doping for forming a p-type impurity region of a TFD to be conducted in a single step, which significantly simplifies the manufacturing process.

In the method where the doping is conducted onto the first and the second island-shaped semiconductor layers simultaneously as described above, if the thickness “d1” of the first island-shaped semiconductor layer (i.e., the thickness of the first crystalline semiconductor film), the thickness “d3” of the gate insulating film, and the thickness “d2” of the second island-shaped semiconductor layer (i.e., the thickness of the second crystalline semiconductor film for the TFD) satisfy the relationship d1+d3<d2, advantages as described with reference to FIG. 1(b) can be obtained.

That is, even if the doping condition (the peak depth) is optimized for the first island-shaped semiconductor layer that is destined to become the active region of a TFT to make the resistance of the source and drain regions low, the impurity will not be implanted relatively deep into depth “d2” of the second island-shaped semiconductor layer, which is destined to become the active region of a TFD. Therefore, the crystal destruction caused by the implantation damage can be suppressed to more efficiently at the bottom surface of the second island-shaped semiconductor layer (the interface between the second island-shaped semiconductor layer and the gate insulating film), which is destined to become the active region of the TFD, than at the bottom surface of the first island-shaped semiconductor layer, which is destined to become the active region of the TFT. As a result, although the bare-doping is conducted into the second island-shaped semiconductor layer, the crystallinity can still be restored by the heat treatment to be performed later. Consequently, the resistance of the n-type region or the p-type region of the TFD can be made low. Doping conditions required for each of the semiconductor layers can thus be independently implemented. A semiconductor device in which a TFT and a TFD having semiconductor layers optimized for their respective purposes and possessing favorable characteristics are formed on a single substrate can be provided without increasing the number of manufacturing steps and at a low manufacturing cost.

According to the manufacturing method in this embodiment, the doping of an n-type impurity element into a region of the second island-shaped semiconductor layer that is destined to become an n-type region, and the doping of a p-type impurity element into a region of the second island-shaped semiconductor layer that is destined to become a p-type region are preferably conducted such that a region into which no impurity is doped (intrinsic region) in either of the doping processes is formed between a region of the second island-shaped semiconductor layer that is destined to become an n-type region and a region of the second island-shaped semiconductor layer that is destined to become a p-type region.

In the manufacturing method in this embodiment, when forming, on the gate insulating film, an gate electrode of a thin film transistor, the manufacturing process can be simplified by forming the second island-shaped semiconductor layer destined to become the active region of a thin film diode and at least a portion of the gate electrode simultaneously by utilizing the second crystalline semiconductor film of which the active region of the TFD is formed in a single layer.

A light-transmissive substrate can be used as a substrate of this embodiment. In that case, the manufacturing method of this embodiment preferably includes a step of forming a light-shielding layer for blocking light from the back of the substrate on the bottom of a region over which the second island-shaped semiconductor layer is formed. With the light-shielding layer, the light projected from the backlight behind the back of the substrate can effectively be blocked, which enables the TFD to detect the light from above only. More preferably, the first crystalline semiconductor film is patterned to form the first island-shaped semiconductor layer, which is destined to become the active region of the thin film transistor, and at least a portion of the light-shielding layer simultaneously. This method can further simplify the manufacturing process.

In this embodiment, the first crystalline semiconductor film may also be formed by preparing a substrate with an amorphous semiconductor film formed thereon, and by crystallizing the amorphous semiconductor film by irradiating the amorphous semiconductor film with laser light. With this method, a crystalline semiconductor film with a high level of crystallinity can be obtained, which provides a higher performance TFT.

More preferably, the first crystalline semiconductor film is formed by the steps of: preparing a substrate with an amorphous semiconductor film formed thereon; adding a catalytic element that facilitates crystallization to the amorphous semiconductor film; and crystallizing the amorphous semiconductor film by conducting a heat treatment on the amorphous semiconductor film to which the catalytic element has been added. By adding a metal element that can facilitate the crystallization to the amorphous semiconductor film, and then conducting a heat treatment for crystallization, a higher quality crystalline semiconductor film having better oriented crystals than a crystalline semiconductor film crystallized by a general laser irradiation only can be obtained. The TFT performance can further be enhanced by utilizing this higher quality first crystalline semiconductor film as the active region of the TFT.

Also, in this embodiment, the second crystalline semiconductor film can also be formed by forming a second crystalline semiconductor film directly on the gate insulating film with the plasma CVD. This method is effective in particular when the thickness of the second crystalline semiconductor film is large. The thicker the film, the better crystallinity the film has. Therefore, it is advantageous to use this method for formation of the second crystalline semiconductor film, which is preferably thicker than the first crystalline semiconductor film for better TFD characteristics. When the second crystalline semiconductor is formed, the first crystalline semiconductor film has already been patterned at least, and therefore the heating temperature is preferably as low as possible, taking into consideration of the possible thermal deformation (heat shrinking) of the glass substrate. By directly forming a crystalline semiconductor film with the plasma CVD method, the heating temperature for the substrate can be suppressed to 450° C. or lower, and a higher precision in the pattern alignment, which is performed later, can be obtained.

### Embodiment 1

Embodiment 1 of a semiconductor device of the present invention is described below. A semiconductor device according to this embodiment has an n-channel type TFT and a TFD on a single substrate, and is used, for example, as an active matrix type display device equipped with a sensor section.

FIG. 2 is a schematic cross-sectional view of an example of the semiconductor device according to this embodiment. Although the semiconductor device of this embodiment typically has a plurality of TFTs and a plurality of TFDs on a single substrate, here, a configuration with a single TFT and a single TFD is illustrated.

A semiconductor device according to this embodiment includes a thin film transistor 124 and a thin film diode 125 formed on a substrate 101 via base films 103 and 104. The thin film transistor 124 includes a semiconductor layer 107 that includes a channel region 115 and source and drain regions 113, a gate insulating film 108 disposed on the semiconductor layer 107, a gate electrode 109 controlling the conductivity of the channel region 115, and electrodes/wirings 122 connected to source and drain regions 113, respectively. On the other hand, a thin film diode 125 has a semiconductor layer 110 formed on the gate insulating film 108 of the thin film transistor and including at least an n-type region 114 and a p-type region 118, and also has electrodes/wirings 123 connected to the n-type region 114 and the p-type region 118, respectively. The semiconductor layer 110 of the thin film diode 125 is in contact with the top surface of the gate insulating film 108. In the example illustrated, an intrinsic region 119 is interposed between the n-type region 114 and the p-type region 118 of the semiconductor layer 110.

A silicon nitride film 120 and a silicon oxide film 121 are formed as interlayer insulating films over the thin film transistor 124 and the thin film diode 125. A light-shielding layer 102 is interposed between the semiconductor layer 110 of the thin film diode 125 and the substrate 101.

The semiconductor layer 107 of the thin film transistor 124 and the semiconductor layer 110 of the thin film diode 125 are crystalline semiconductor layers formed of different crystalline semiconductor films. Here, thickness “d2” of the semiconductor layer 110 of the thin film diode 125 is greater than thickness “d1” of the semiconductor layer 107 of the thin film transistor 124. In the example illustrated, thickness “d2” of the semiconductor layer 110 of the thin film diode 125 is greater than the sum of the thickness “d1” of the semiconductor layer 107 of the thin film transistor 124 and thickness “d3” of the gate insulating film 108 (i.e., d1+d3).

The n-channel type thin film transistor 124 and the thin film diode 125 as shown in FIG. 2 are manufactured as follows, for example.

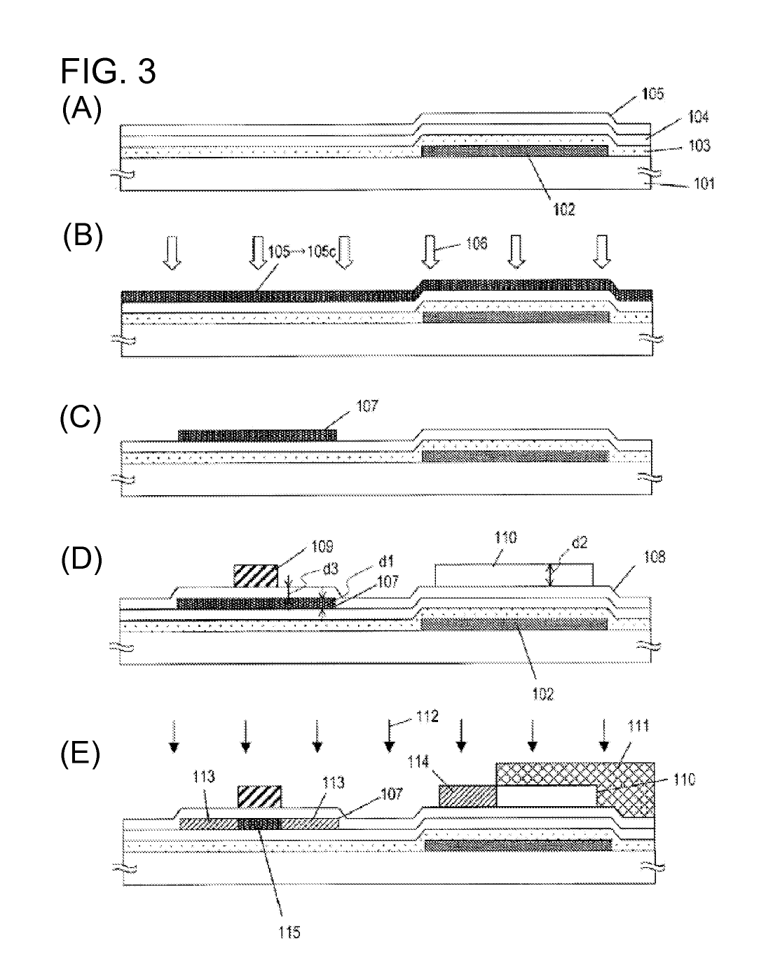

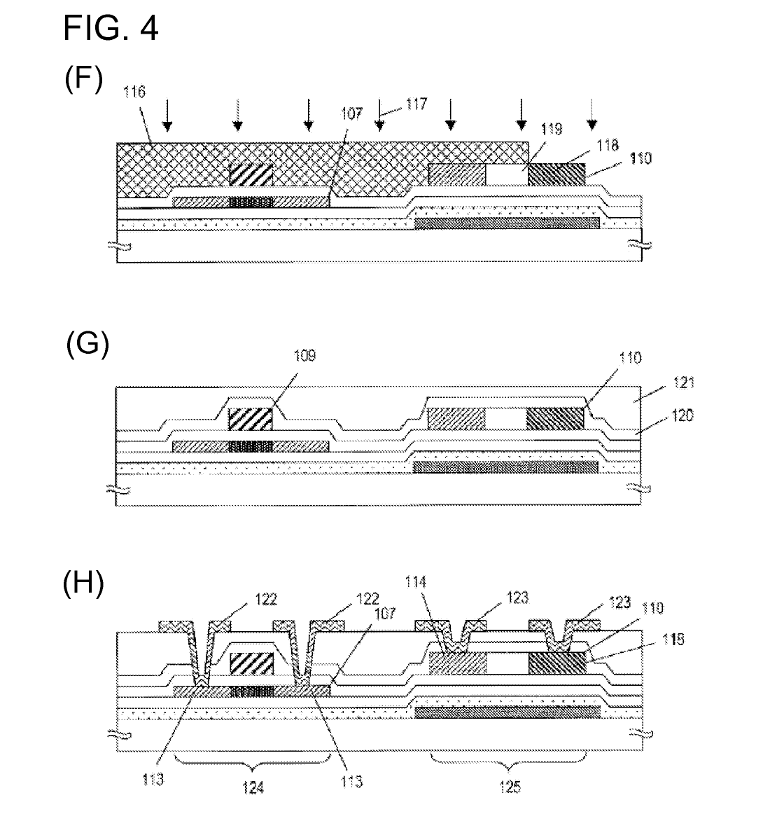

FIG. 3 and FIG. 4 are cross-sectional views illustrating the steps of manufacturing the thin film transistor 124 and the thin film diode 125 according to this embodiment. Manufacturing steps proceed sequentially from FIG. 3(A) to FIG. 4(H).

First, as shown in FIG. 3(A), on the surface of the substrate 101 on which a TFT and a TFD are to be formed, a light-shielding layer 102, a first base film 103, a second base film 104, and an amorphous semiconductor film 105 are formed in this order.

The substrate 101 can be a low alkali glass substrate or a quartz substrate. In this embodiment, a low alkali glass substrate is used. In this case, the substrate may be pre-heat treated at a temperature that is lower than the glass strain point by about 10 to 20° C.

The light-shielding layer 102 is disposed such that it blocks light from the back of the substrate towards the TFD in the finished product. The light-shielding layer 102 can be formed of a metal film, a silicon film, or the like. When a metal film is used, the metal film preferably has a high melting point, such as tantalum (Ta), tungsten (W), or molybdenum (Mo), in consideration of the heat treatment to be conducted later in the manufacturing process. In this embodiment, Mo film was deposited by sputtering, and then patterned to form the light-shielding layer 102. The thickness of the light-shielding layer 102 is 30 to 200 nm, or preferably 50 to 150 nm. It is 100 nm, for example, in this embodiment.

Base films 103 and 104 can be formed of a silicon oxide film, silicon nitride film, silicon nitride oxide film, or the like to prevent any diffusion of the impurity from the substrate 101. In this embodiment, for example, a silicon nitride oxide film was formed by the plasma CVD method using SiH₄, NH₃, and N₂O material gases as the first base film 103, which is the lower layer. Similarly, a second base film 104 was formed on the lower layer by the plasma CVD method using SiH₄ and N₂O material gases. The thickness of the silicon nitride oxide film of the first base film 103 is set to 30 to 400 nm (200 nm, for example). The thickness of the silicon oxide film of the second base film 104 is set to 50 to 300 nm (100 nm, for example). In this embodiment, two layers of base films are used, but a one layer base film (a silicon oxide film, for example) can alternatively be used.

Using a known method such as the plasma CVD or sputtering, an amorphous silicon film (a-Si film), for example, is formed as an amorphous semiconductor film 105. The thickness of the a-Si film 105 is set to 20 nm or greater and 100 nm or less, or preferably 30 to 70 nm. In this embodiment, the plasma CVD method is used to form the a-Si film 105 (thickness: 50 nm). Because the base films 103 and 104 and the amorphous silicon film 105 can be formed with the same formation method, these films may be formed continuously. In this way, the base films are not exposed to the atmosphere after being formed, which prevents the surface contamination and therefore reduces the characteristics variations and the threshold voltage fluctuation of the TFTs to be fabricated.

Next, the a-Si film 105 is heated for several tens of minutes to several hours at 400 to 550° C. to release hydrogen in the a-Si film 105. Subsequently, as shown in FIG. 3(B), irradiation with laser light 106 is performed. The a-Si film 105 is melt-solidified by the irradiation with the laser light 106, and crystallized in the process to become a crystalline silicon film (first crystalline silicon film) 105c.

A pre-heat treatment for hydrogen removal is conducted on the a-Si film 105 prior to the crystallization treatment by irradiation with laser light, because an a-Si film formed with a regular CVD method contains a large amount of hydrogen, and therefore if the film is irradiated with laser light without being subjected to the pre-heat treatment, there will be hydrogen bumping, which can lead to a film chipping.

The laser light 106 can be a XeCl excimer laser (wavelength: 308 nm) or a KrF excimer laser (wavelength: 248 nm). The laser light 106 is formed to have a beam spot that appears as an elongated shape on the surface of the substrate 101. The entire substrate is crystallized by the sequential scanning in the direction perpendicular to the direction of the longer side of the beam spot shape. Preferably the scanning is conducted such that beams partially overlap one another, because, in this way, the laser is radiated multiple times into a given point on the a-Si film 105, thereby improving the uniformity. In this embodiment, the laser beam is formed to have a beam spot that appears as an elongated shape of 300 mm×0.4 mm on the surface of the substrate 101, and the scanning is conducted sequentially in the direction perpendicular to the direction of the longer side of the beam spot with a step interval of 0.02 mm. That is, at any given point on the silicon film, the laser is radiated 20 times in total. Here, YAG laser, YVO₄ laser, or the like can also be used as the laser light as well as the aforementioned KrF excimer laser and XeCl excimer laser, which are a pulse oscillation type or a continuous light-emitting type. The laser radiation energy density is 250 to 450 mJ/cm² (350 mJ/cm², for example).

Next, as shown in FIG. 3(C), unnecessary region of the first crystalline silicon film 105c is removed to make separate elements. This process provides an island-shaped semiconductor layer 107, which is destined to become the active region (source and drain regions and a channel region) of a TFT.

Next, as shown in FIG. 3(D), a gate insulating film 108 is formed to cover an island-shaped semiconductor layer 107, and then, a gate electrode 109 of TFT and an island-shaped semiconductor layer 110, which is destined to become the active region (n-type region, p-type region, and intrinsic region) of a TFD are formed.

The gate insulating film 108 is preferably a silicon oxide film having a thickness of 20 to 150 nm. Here, a 100 nm thick silicon oxide film is used.

The gate electrode 109 can be formed by depositing a conductive film on the gate insulating film 108 by sputtering, CVD, or like method, and then patterning it. Preferably, the conductive film is made of W, Ta, Ti, or Mo, which are metals having high melting points, or their alloy materials. The thickness of the conductive film is preferably 300 to 600 nm. In this embodiment, a molybdenum (Mo) film having a thickness of 450 nm is used as the conductive film.

The island-shaped semiconductor layer 110 is formed by forming a second crystalline silicon film on the gate insulating film 108 and then patterning it. The second crystalline silicon film can be formed by the plasma CVD method using the SiH₄ gas as a material at a substrate heating temperature of 300 to 450° C. Here, hydrogen is used as the diluent gas. By setting the hydrogen dilution ratio (SiH₄/H₂) to 1/50 or lower, the film acquires the crystal component when it is formed. For a higher crystallization rate, the dilution ratio should be higher. However, a higher dilution ratio slows down the film formation. Therefore, the dilution ratio is preferably within a range of 1/50 to 1/1000. Ar gas may be added to the diluent gas. The pressure was set to 1 to 4 Torr (2.5 Torr, for example). RF power was set to 0.2 to 3 kW/m² (2 kW/m², for example). The second crystalline silicon film is directly formed in this manner. When a crystalline semiconductor film such as a crystalline silicon film is described herein as “directly formed,” it means that the crystalline semiconductor film is deposited; it does not include the case that an amorphous semiconductor film is deposited and then crystallized to form a crystalline semiconductor film, for example. The gate electrode 109 and the semiconductor layer 110 may be formed in either order.

Preferably, the thickness “d2” of the island-shaped semiconductor layer 110 is set greater than the thickness “d1” (here, it is 50 nm) of the semiconductor layer 107, which is destined to become the active region of TFT. More preferably, it is set greater than the sum of the thickness “d3” of the gate insulating film 108 (here, it is 100 nm) and the thickness “d1” of the semiconductor layer 107 (here, it is 150 nm). Here, the thickness “d2” of the island-shaped semiconductor layer 110 was set to 250 nm.

Next, as shown in FIG. 3(E), a mask 111, which is made of a resist, is formed to cover a portion of the island-shaped semiconductor layer 110, which layer 110 is destined to become the active region of TFD. Then, an n-type impurity (phosphorus) 112 is ion-doped into the entire area from above the substrate 101. Phosphorus 112 is ion-doped into the island-shaped semiconductor layer 107, which is destined to become the active region of TFT, through the gate insulating film 108. Phosphorus 112 is also ion-doped into the island-shaped semiconductor layer 110, which is destined to become the active region of TFD, directly (bare-doping). In this process, phosphorus 112 is implanted into the region in the island-shaped semiconductor layer 110 of TFD that is not covered by the resist mask 111 and the regions in the semiconductor layer 107 of TFT that is not covered by the gate electrode 109. Phosphorus 112 is not doped into regions covered by the resist mask 111 or by the gate electrode 109. In this way, for the semiconductor layer 107 of a TFT, the regions into which the phosphorus 12 was implanted become the source and drain regions 113 of the TFT, and the region that was covered by the gate electrode 109 and therefore phosphorus 112 was not implanted becomes the channel region 115 of the TFT. For the island-shaped semiconductor layer 110 of the TFD, the region to which phosphorus 112 was implanted becomes the n⁺ region 114 of the TFD.

Here, the thickness “d1” of semiconductor layer 107, the thickness “d2” of the semiconductor layer 110, and the thickness “d3” of the gate insulating film 108 satisfy the relationship d1+d3<d2. Therefore, the doping conditions can be optimized for the semiconductor layer 107, which is destined to become the active layer of a TFT, thereby making the source and drain regions 113 low resistance. The impurity is implanted not deep into depth “d2” of the semiconductor layer 110, which is destined to become the active layer of a TFD. Although the implantation is bare-doping, the doping damage near the bottom surface of the semiconductor layer 110 can be suppressed to smaller than that of the semiconductor layer 107, which is destined to become the active layer of a TFT.

Next, as shown in FIG. 4(F), after the resist mask 111 used in the previous step is removed, a mask 116 is formed of a resist to cover a portion of the island-shaped semiconductor layer 110, which layer 110 is destined to become the active region of TFD, and to cover the entire island-shaped semiconductor layer 107, which is destined to become the active region of a TFT. Then, a p-type impurity (boron) 117 is ion-doped from above the substrate 101 over the entire surface. By this process, boron 117 is implanted into the region in the island-shaped semiconductor layer 110 that is not covered by the resist mask 116. Boron 117 is not doped into the region covered by the resist mask 116. Consequently, the region in the island-shaped semiconductor layer 110 of the TFD to which boron 117 was implanted becomes a p⁺ region 118 of the TFD, and of the region into which the phosphorus was not implanted in the previous step, the region the boron 117 was not implanted becomes an intrinsic region 119.

Next, after the resist mask 116 used in the previous step is removed, a heat treatment is conducted under an inert atmosphere, such as a nitrogen atmosphere. With this heat treatment, the source and drain regions 113 of the TFT and the n⁺ region 114 and p⁺ region 118 of the TFD can recover from doping damages such as crystal defects that they suffered during the doping. The phosphorus and boron doped into these regions are also activated. Here, if the thicknesses “d1,” “d2,” and “d3” of the semiconductor layers 107 and 110 are adjusted to minimize the damage at the bottom surface of the respective semiconductor layers, recrystallization occurs starting from the bottom surface where the crystal destruction is minimum. As a result, favorable crystalline state is restored at both the source and drain regions 113 of the TFT and the n⁺ region 114 and the p⁺ region 118 of the TFD, which make them low resistance. For the heat treatment, a regular heating furnace can be used, but RTA (Rapid Thermal Annealing) is more preferably used. In particular, the one that sprays a high-temperature inert gas to the substrate surface to raise/lower the temperature instantly is suitable.

Next, as shown in FIG. 4(G), a silicon oxide film or a silicon nitride film is used to form an interlayer insulating films 120 and 121. In this embodiment, an interlayer insulating film having a two-layered structure composed of the silicon nitride film 120 and the silicon oxide film 121 is formed. After the interlayer insulating film is formed, annealing is conducted at 350 to 450° C. under 1 atm of nitrogen atmosphere or hydrogen mixture atmosphere to hydrogenize the semiconductor layer 107 of the TFT and semiconductor layer 110 of the TFD to reduce the crystal defects. That is, dangling bonds in the crystalline semiconductor layer 107 of the TFT and in the crystalline semiconductor layer 110 of the TFD are inactivated by termination with hydrogen atoms to improve the crystal quality. If the silicon nitride film 120 is formed to include hydrogens, those hydrogens in the silicon nitride film 120 can be utilized for this purpose, which is efficient.

Next, as shown in FIG. 4(H), contact holes are formed in the silicon nitride film 120 and the silicon oxide film 121, which constitute the interlayer insulating film, and electrodes/wirings 122 for the TFT and electrodes/wirings 123 for the TFD are formed using a metal material. This completes a thin film transistor 124 and a thin film diode 125. A protective film made of silicon nitride film or the like may be provided over the thin film transistor 124 and the thin film diode 125 to protect these elements, as necessary.

According to the method described above, semiconductor layers for the TFT and the TFD, in particular the channel region of the TFT and the intrinsic region of an optical sensor TFD, can be made separately. As a result, respective optimum element characteristics required for the TFT and for the optical sensor TFD can simultaneously be obtained.

### Embodiment 2

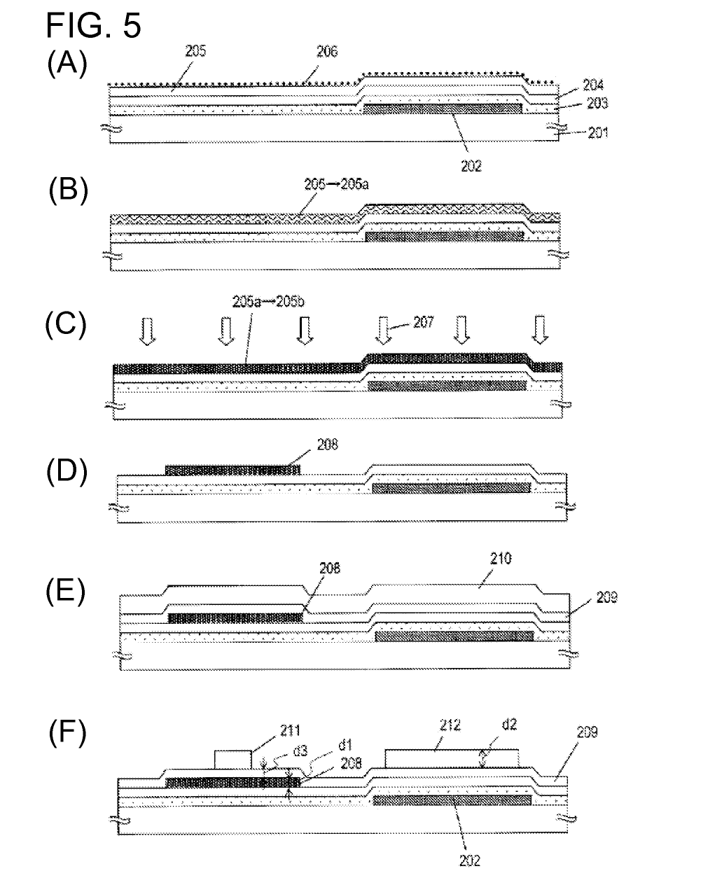

Below, with reference to FIG. 5, a semiconductor device according to Embodiment 2 of the present invention is described. The method for manufacturing a semiconductor device according to this embodiment differs from the manufacturing method of Embodiment 1 in that in this embodiment, the semiconductor layer for the TFT is formed by crystallizing an amorphous semiconductor film using a catalytic element, and the gate electrode of the TFT and the semiconductor layer for the TFD are formed of the same crystalline semiconductor film.

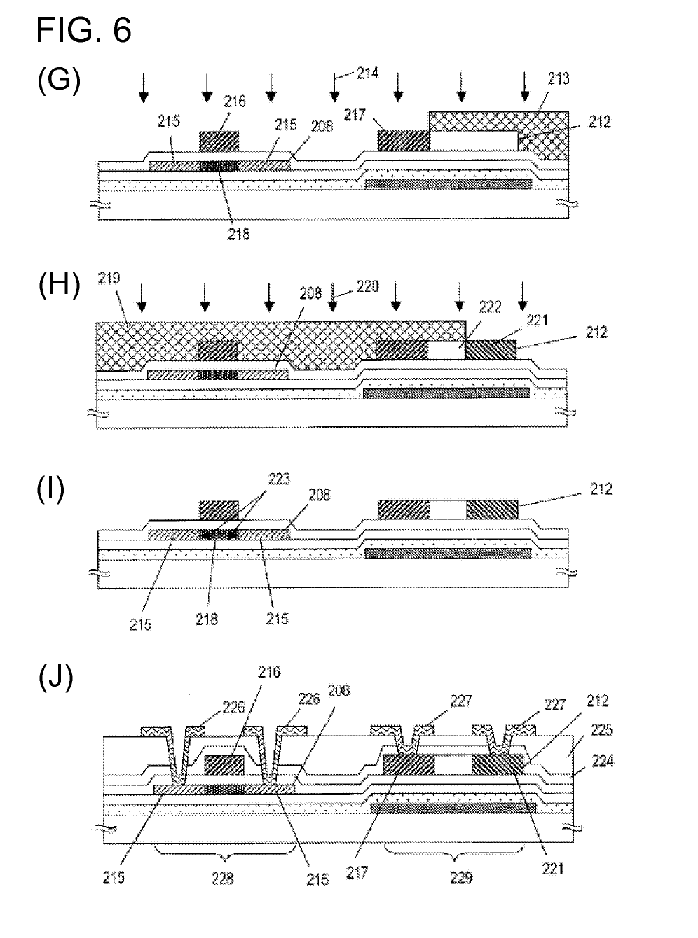

FIG. 5 and FIG. 6 are cross-sectional views illustrating the steps of manufacturing a thin film transistor 228 and a thin film diode 229, which are described below. Manufacturing steps proceed sequentially from FIG. 5(A) to FIG. 6(J).

First, as shown in FIG. 5(A), on the surface of a glass substrate 201 on which a TFT and a TFD are to be formed, a light-shielding layer 202, a first base film 203, a second base film 204 and an amorphous semiconductor film 205 are formed in this order.

A light-shielding layer 202 is disposed such that it blocks the light from the back of the substrate so that the light does not enter the semiconductor layer for the TFD in the finished product. In this embodiment, a Mo film was deposited by sputtering, and then patterned to form the light-shielding layer 202. The thickness of the light-shielding layer 202 was set to 100 nm as an example.

Base films 203 and 204 can be formed of a silicon oxide film, silicon nitride film, silicon nitride oxide film, or the like to prevent any diffusion of the impurity from the substrate 201. In this embodiment, a silicon nitride film, as an example, was formed as the first base film 203, which is the lower layer, and a silicon oxide film was formed on the first base film 203 as the second base film 204. The thickness of the first base film 203 (silicon nitride film) is set to 200 nm, for example. The thickness of the second base film 204 (silicon oxide film) is set to 100 nm, for example. In this embodiment, two layers of base films are used, but a one layer base film (a silicon oxide film, for example) can alternatively be used.

Using a known method such as the plasma CVD or sputtering, an amorphous silicon film (a-Si film), for example, is formed as an amorphous semiconductor film 205. The thickness of an a-Si film 205 is set to 20 nm or greater and 100 nm or less, or preferably 30 to 70 nm. In this embodiment, the plasma CVD method is used to form the a-Si film 205 (thickness: 50 nm). Since the base films 203 and 204 and the a-Si film 205 can be formed with the same formation method, these films may be formed continuously.

Next, a catalytic element is added to the surface of the a-Si film 205. That is, the a-Si film 205 is coated with an aqueous solution containing 5 ppm in weight, for example, of a catalytic element (which is nickel in this embodiment and therefore the solution is a nickel acetate solution) by the spin coating method to form a catalytic element contained layer 206. Catalytic elements that can be used include: iron (Fe), cobalt (Co), tin (Sn), lead (Pb), palladium (Pd), and copper (Cu), as well as nickel (Ni). Any one of these elements or a combination of these elements may be used. Other possible catalytic elements, which have smaller catalytic effects, include: ruthenium (Ru), rhodium (Rh), osmium (Os), iridium (Ir), platinum (Pt), and gold (Au). Here, only an extremely small amount of catalytic element is doped. The concentration of the catalytic element on the surface of the a-Si film 205 is controlled by the total reflection x-ray fluorescence (TRXRF) method, and it is about 5×10¹² atoms/cm² in this embodiment. Prior to this process, the surface of the a-Si film 205 may optionally be oxidized slightly with ozone water or the like to improve the wettability of the a-Si film 205 surface for the spin coating.

In this embodiment, nickel is doped using the spin coating method. However, the vapor deposition, sputtering, or the like technique may be used to form a thin film containing a catalytic element (a nickel film in this embodiment) on the a-Si film 205.

Subsequently, a heat treatment is conducted under an inert atmosphere, such as a nitrogen atmosphere. As the heat treatment, preferably an annealing is conducted at 550 to 620° C. for 30 minutes to 4 hours. In this embodiment, a heat treatment at 590° C. was conducted for an hour as an example. In this heat treatment, the nickel that has been added to the a-Si film surface diffuses into the a-Si film 205, and silicidation occurs. Crystallization of the a-Si film 205 proceeds from the silicided portions as nuclei. As a result, as shown in FIG. 5(B), the a-Si film 205 is crystallized to become a crystalline silicon film 205a. Here, crystallization was conducted by a heat treatment using a heating furnace. However, crystallization can alternatively be conducted with an RTA (Rapid Thermal Annealing) device in which a lamp or the like is used as a heat source.

Next, as shown in FIG. 5(C), the crystalline silicon film 205a obtained by the heat treatment is irradiated with laser light 207 to further recrystallize the crystalline silicon film 205a to form a crystalline silicon film 205b, which has an improved crystal quality. The laser light used here can be an XeCl excimer laser (wave length: 308 nm) or a KrF excimer laser (wavelength: 248 nm). The laser light is formed to have a beam spot that appears as an elongated shape on the surface of the substrate 201. The entire substrate is crystallized by the sequential scanning in the direction perpendicular to the direction of the longer side of the beam spot shape. By performing the scanning so that beams partially overlap one another, the laser is radiated multiple times into a given point on the crystalline silicon film 205a, which improves the uniformity. In this embodiment, the laser beam is formed to have a beam spot that appears as an elongated shape of 300 mm×0.4 mm on the surface of substrate 201, and the scanning is conducted sequentially in the direction perpendicular to the direction of the longer side of the beam spot with a step interval of 0.02 mm. That is, at any given point on the crystalline silicon film 205a, the laser is radiated 20 times in total.

Here, YAG laser, YVO₄ laser, or the like can also be used as well as the aforementioned KrF excimer laser and XeCl excimer laser, which are a pulse oscillation type or a continuous light-emitting type. The laser radiation energy density is set to 250 to 450 mJ/cm² (330 mJ/cm², for example). In this embodiment, unlike Embodiment 1, there is an additional limitation that the crystalline state of the crystalline silicon film 205a obtained in the previous manufacturing step is reset if the laser light energy density is too high. Therefore, it is desirable that the energy density is set to a lower value than in Embodiment 1.

As described above, the crystalline silicon film 205a obtained by solid-phase crystallization is irradiated with laser light for melt-solidification to reduce the crystal defect, and becomes a higher quality crystalline silicon film 205b. The crystal plane orientation of the crystalline silicon region 205b thus obtained is almost determined in the solid-phase crystallization process in which a catalytic element is used. It is a characteristic plane orientation mainly composed of <111>zone planes. Among them, more than 50% of the total region is occupied by the (110) plane orientation and the (211) plane orientation. The diameter of the crystal domain (a region in which the plane direction is about the same) was 2 to 5 μm.

Subsequently, as shown in FIG. 5(D), unnecessary regions of the crystalline silicon film 205b are removed for device separation. This process provides an island-shaped semiconductor layer 208, which is destined to become the active region (source and drain regions and a channel region) of a TFT.

Next, as shown in FIG. 5(E), a gate insulating film 209 is formed to cover the island-shaped semiconductor layer 208, and a second crystalline silicon film 210 is formed on the gate insulating film 209. For the gate insulating film 209, preferably a silicon oxide film having a thickness of 20 to 150 nm is used. Here, a silicon oxide film having a thickness of 100 nm is used. The second crystalline silicon film 210 is formed by the plasma CVD using SiH₄ gas as a material by directly depositing the crystalline silicon film under the similar conditions as in Embodiment 1. In this embodiment, the thickness of the second crystalline silicon film 210 is set to 300 nm.

The method for forming the second crystalline silicon film is not limited to the one described above. Other possible crystallization methods include the technique used to form the first crystalline silicon film in this embodiment, i.e., a method in which a catalytic element is added to an amorphous silicon film and the film is subjected to a heat treatment for crystallization, and a method in which crystallization takes place by irradiating the amorphous silicon film with laser light.

Subsequently, as shown in FIG. 5(F), the second crystalline silicon film 210 is patterned to form a semiconductor layer 211 destined to become the gate electrode of the TFT, and an island-shaped semiconductor layer 212 destined to become the active region (n-type region, p-type region, and the intrinsic region) of the TFD. Preferably, the thickness “d2” of the island-shaped semiconductor layer 212 is set greater than the thickness “d1” of the semiconductor layer 208 (here, it is 50 nm), which layer 208 is destined to become the active region of the TFT. More preferably, the thickness “d2” is set greater than the sum of the thickness “d3” of the gate insulating film 209 (here, it is 100 nm) and the thickness “d1” of the semiconductor layer 208 (here, it is 150 nm). Here, the thickness “d2” of the island-shaped semiconductor layer 212 is substabtially the same as the thickness of the second crystalline silicon film 210, which is 300 nm, for example.

Next, as shown in FIG. 6(G), a mask 213 made of a resist is formed to cover a portion of the island-shaped semiconductor layer 212, which island-shaped semiconductor layer 212 is destined to become the active region of TFD. Then, n-type impurity (phosphorus) 214 is ion-doped from above the substrate 201 into the entire surface. Here, the phosphorus 214 is ion-doped into the island-shaped semiconductor layer 208, which is destined to become the active region of the TFT, through the gate insulating film 209, and is ion-doped into the island-shaped semiconductor layer 212, which is destined to become the active region of the TFD, directly (bare-doping). In this process, phosphorus 214 is implanted into a region in the island-shaped semiconductor layer 212 of the TFD that are not covered by the resist mask 213 and into regions in the semiconductor layer 208 of TFT that are not covered by the semiconductor layer 211. The phosphorus 214 is also bare-implanted into the semiconductor layer 211 made of a crystalline silicon to obtain a gate electrode 216 made of the crystalline silicon that became n-type. The phosphorus 214 is not doped into the regions of the semiconductor layer covered by the resist mask 213 or the gate electrode 216. That is, of the semiconductor layer 208 of TFT, the regions into which the phosphorus 214 was implanted become the source and drain regions 215 of the TFT, and the region that was covered by the gate electrode 216 and therefore the phosphorus 214 was not implanted into becomes the channel region 218 of the TFT. Of the island-shaped semiconductor layer 212 of the TFD, the region into which the phosphorus 214 was implanted becomes the n⁺ region 217 of TFD.

Here, the doping condition is preferably optimized for the semiconductor layer 208 destined to become the active layer of the TFT. With the optimized doping condition, the source and drain regions 215 can be made low resistance. Also, the thickness “d1” of the semiconductor layer 208, the thickness “d2” of the semiconductor layer 212, and the thickness “d3” of the gate insulating film 209 satisfy the relationship d1+d3<d2. As a result, in this doping process, the impurity is not implanted deeper into the semiconductor layer 212, which is destined to become the active layer of the TFD beyond the thickness “d2.” Therefore, although the implantation is bare-doping, the doping damage near the bottom surface of the semiconductor layer 212 is suppressed to smaller than that of the semiconductor layer 208, which is destined to become the active layer of TFT. The gate electrode 216 is similar to the semiconductor layer 212, which is destined to be the active layer of the TFD. Therefore, although the implantation is bare-doping, the doping damage near the bottom surface of the gate electrode 216 is suppressed to smaller than that of the semiconductor layer 208, which is destined to become the active layer of the TFT.

Next, after the resist mask 213 used in the previous manufacturing step is removed, as shown in FIG. 6(H), a mask 219 made of a resist is formed to cover a portion of the island-shaped semiconductor layer 212, which is destined to become the active region of the TFD, and to cover the entire island-shaped semiconductor layer 208, which is destined to become the active region of the TFT. Subsequently, a p-type impurity (boron) 220 is ion-doped from above the substrate 201 into the entire surface. In this manufacturing step, the boron 220 is implanted into the region in the island-shaped semiconductor layer 212 of the TFD that is not covered by the resist mask 219. The boron 220 is not doped into the region covered by the resist mask 219. By this doping process, in the island-shaped semiconductor layer 212 of the TFD, the region to which boron 220 was implanted becomes the p⁺ region 221 of the TFD, and of the region into which the phosphorus was not implanted in the previous manufacturing step, the region into which the boron 220 was not implanted becomes the intrinsic region 222.

Next, after the resist mask 219 used in the previous manufacturing step is removed, a heat treatment is conducted under an inert atmosphere, such as a nitrogen atmosphere. FIG. 6(I) illustrates the manufacturing process at this stage. With this heat treatment, the source and drain regions 215 of the TFT, the n⁺ region 217 and p⁺ region 221 of the TFD, and the gate electrode 216 of the TFT recover from doping damages such as crystal defects that they suffered during the doping, and the phosphorus and boron doped into these regions are activated. Here, in the semiconductor layer 208 of TFT, semiconductor layer 212 of the TFD, and the gate electrode 216 of the TFT, which is the same layer as the semiconductor layer 212 of the TFD, the damage of the bottom surface of each of the semiconductor layers is suppressed, as described above. Therefore, recrystallization occurs starting from the bottom surface of the semiconductor layer where the crystal destruction is minimal towards the top surface. As a result, a good crystalline state is recovered in the source and drain regions 215 of the TFT, the n⁺ region 217 and p⁺ region 221 of the TFD, and the gate electrode 216 of the TFT, thereby making these regions low resistance.

Furthermore, in this heat treatment, the phosphorus doped into the source and drain regions 215 of the semiconductor layer 208 of the TFT increases the solid solubility of nickel in the regions. The nickel present in the channel region 218 is transferred from the channel region 218 to the source and drain regions 215, in the direction indicated by the arrows 223. As a result, the nickel moves into the source and drain regions 215 of the TFT, increasing the nickel concentration in these regions beyond the nickel concentration in the channel region 218 to 1×10¹⁸/cm³ or higher. For the heat treatment, a common heating furnace can be used. However, the RTA (Rapid Thermal Annealing) is more desirable. In particular, the RTA in which a high temperature inert gas is sprayed on the substrate surface to raise/lower the temperature instantly is suitable.

Next, as shown in FIG. 6(J), a silicon oxide film or a silicon nitride film is formed as an interlayer insulating films 224 and 225. In this embodiment, an interlayer insulating film having a two-layer structure, including the silicon nitride film 224 and the silicon oxide film 225 is formed. After the interlayer insulating film is formed, annealing is conducted at 350 to 450° C. under 1 atm of nitrogen atmosphere or hydrogen mixture atmosphere to hydrogenize the semiconductor layer 208 of the TFT and the semiconductor layer 212 of the TFD to reduce the crystal defects. That is, dangling bonds in the crystalline semiconductor layer 208 of the TFT and in the crystalline semiconductor layer 212 of the TFD are inactivated by termination with hydrogen atoms to improve the crystal quality. If the silicon nitride film 224 is formed to include hydrogens, those hydrogens in the silicon nitride film 224 can be utilized for this purpose, which is efficient.

Next, contact holes are formed in the silicon nitride film 224 and the silicon oxide film 225, which constitute the interlayer insulating film, and electrodes/wirings 226 for the TFT and electrodes/wirings 227 for the TFD are formed using a metal material. This completes a thin film transistor 228 and a thin film diode 229. A protective film made of a silicon nitride film or the like may be provided over the thin film transistor 228 and the thin film diode 229 to protect these elements as necessary.

According to the method described above, semiconductor layers of the TFT and the TFD, in particular the channel region of the TFT and the intrinsic region of an optical sensor TFD, can be made separately. As a result, respective optimum element characteristics required for the TFT and for the optical sensor TFD can simultaneously be obtained. In this embodiment, in particular, because the crystalline semiconductor layer of TFT is formed by crystallization using the catalytic element, higher TFT performance can be obtained than in the case of Embodiment 1. A circuit configuration having a greater current drive capability, for example, can thus be provided. Also, because the semiconductor layer destined to be the active region of the TFD and the gate electrode of the TFT are formed of the same crystalline silicon film (second crystalline silicon film), the manufacturing process can be simplified, and the manufacturing cost can be reduced.

### Embodiment 3

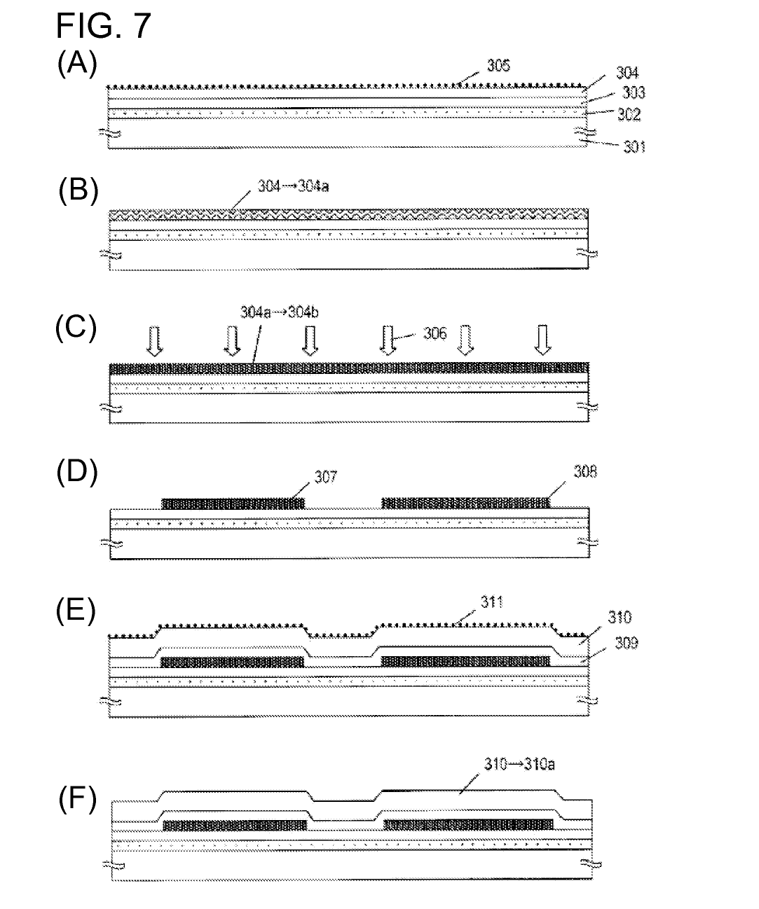

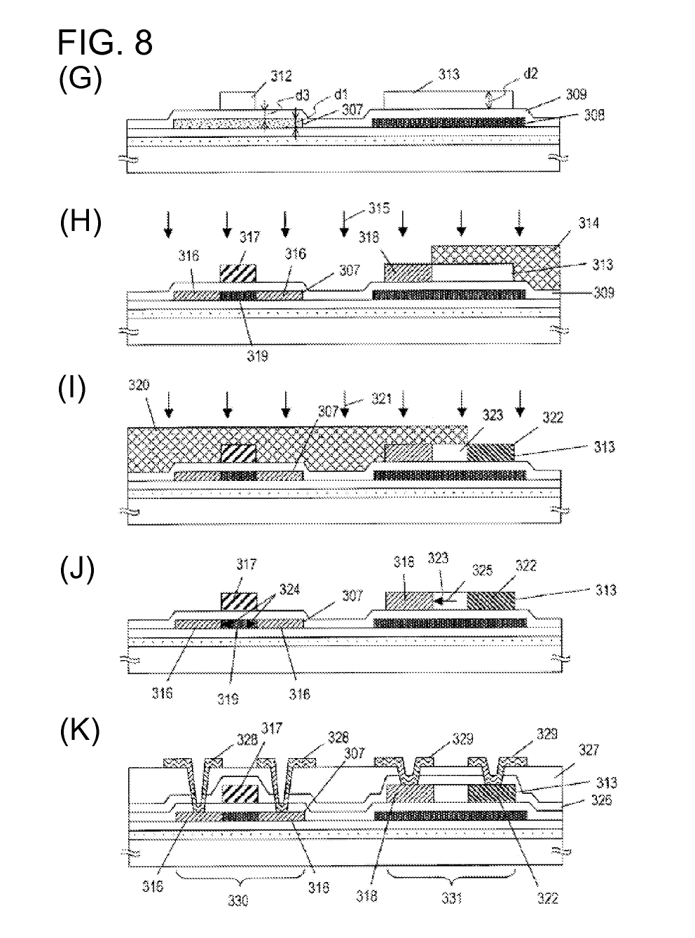

Below, with reference to FIG. 7 and FIG. 8, Embodiment 3 of a semiconductor device according to the present invention is described. According to the method for manufacturing the semiconductor device according to this embodiment, both the semiconductor layers of the TFD and the TFT are formed by crystallizing the amorphous semiconductor film using a catalytic element. Also, the manufacturing method according to this embodiment differs from Embodiment 1 in that the light-shielding layer for TFD is formed of the same crystalline semiconductor film of which the semiconductor layer for the TFT is made, and the gate electrode of TFT is formed of the same crystalline semiconductor film of which the semiconductor layer for TFD is made.

FIG. 7 and FIG. 8 are cross-sectional views illustrating the steps for manufacturing a thin film transistor 330 and a thin film diode 331, which are described below. Manufacturing steps proceed sequentially from FIG. 7(A) to FIG. 8(K).

First, as shown in FIG. 7(A), similar to Embodiment 1 and Embodiment 2, a first base film 302 and a second base film 303a are formed in this order on a substrate 301 (glass substrate, for example) to prevent impurity diffusion from the substrate 301. Here, a silicon nitride film is used as the first base film 302, and a silicon oxide film is used as the second base film 303. Next, an amorphous silicon (a-Si) film 304 having a thickness of 30 to 80 nm (50 nm, for example), is formed. The base films 302 and 303, and the a-Si film 304 may be formed continuously without exposing them to the atmosphere.

Subsequently, a catalytic element is added to the surface of the a-Si film 304. Here, nickel is used as a catalytic element. As in Embodiment 2, a-Si film 304 is coated with an aqueous solution containing 5 ppm in weight, for example, of nickel (therefore the solution is a nickel acetate aqueous solution) by a spin coating method to form a catalytic element contained layer 305. The catalytic element concentration on the surface of the a-Si film 304 is about 5×10¹² atoms/cm².

Next, a heat treatment is conducted under an inert atmosphere, such as a nitrogen atmosphere. In the heat treatment, preferably an annealing is conducted at 550 to 620° C. for 30 minutes to 4 hours. In this embodiment, a heat treatment at 600° C. was conducted for an hour and 30 minutes as an example. In this heat treatment, the nickel that has been added to the a-Si film 304 surface diffuses into the a-Si film 304, and silicidation occurs. Crystallization of the a-Si film 304 proceeds from the silicided portions as nuclei. As a result, as shown in FIG. 7(B), a crystalline silicon film 304a can be obtained.

Next, as shown in FIG. 7(C), a crystalline silicon film 304a obtained by the heat treatment is irradiated with the laser light 306 to further recrystallize the crystalline silicon film 304a to form a crystalline silicon film 304b, which has an improved crystallinity. For the laser light 306, as in Embodiment 1 and Embodiment 2, an XeCl excimer laser (wavelength: 308 nm) is used. Preferably the scanning is performed such that the beams partially overlap one another, because, in this way, a given point on the silicon film is irradiated with the laser multiple times, thereby providing a highly uniform recrystallization of the crystalline silicon film 304a.

Subsequently, as shown in FIG. 7(D), unnecessary regions of the crystalline silicon region 304b are removed for device separation. By this process, an island-shaped semiconductor layer 307, which is destined to become the active region (the source and drain regions and the channel region) of a TFT, and an island-shaped semiconductor layer 308, which is destined to become the light-shielding layer of a TFD, are obtained. The semiconductor layer 308 is disposed in the finished product such that it can shield the light projected from the back of the substrate towards the semiconductor layer for TFD.

Next, as shown in FIG. 7(E), a gate insulating film 309 is formed to cover the island-shaped semiconductor layer 307, which is destined to become the active region of the TFT, and to cover the island-shaped semiconductor layer 308, which is destined to become the light-shielding layer of the TFD, and a second amorphous silicon (a-Si) film 310 is formed on the gate insulating film 309. Thereafter, a catalytic element is added to the second amorphous silicon film 310 to form a catalytic element contained layer 311.

For the gate insulating film 309, preferably a silicon oxide film having a thickness of 20 to 150 nm is used. Here, a silicon oxide film having a thickness of 100 nm is used. Also, the second a-Si film 310 is formed using the plasma CVD method. Here, the thickness of the second a-Si film 310 is set to 300 nm. The gate insulating film 309 and the second a-Si film 310 may be formed continuously by the plasma CVD method.

Nickel is used as a catalytic element for the catalytic element contained layer 311. The second a-Si film 310 is coated with an aqueous solution containing 25 ppm in weight, for example, of nickel (nickel acetate solution), by a spin coating method to form the catalytic element contained layer 311. Here, the catalytic element concentration on the surface of the second a-Si film 310 is about 2×10¹³ atoms/cm².

Subsequently, a heat treatment is conducted under an inert atmosphere, such as a nitrogen atmosphere. In the heat treatment, preferably an annealing is conducted at 550 to 620° C. for 30 minutes to 4 hours. In this embodiment, a heat treatment at 590° C. is conducted for an hour as an example. In this heat treatment, the nickel that has been added to the a-Si film 310 surface diffuses into the a-Si film 310, and silicidation occurs. Crystallization of the second a-Si film 310 proceeds from the silicided portions as nuclei. As a result, as shown in FIG. 7(F), a second crystalline silicon film 310a is obtained.

Next, as shown in FIG. 8(G), the second crystalline silicon film 310a is patterned to form a semiconductor layer 312, which is to become the gate electrode of the TFT, and to form an island-shaped semiconductor layer 313, which is to become the active region (n-type region, p-type region, and intrinsic region) of the TFD. Preferably, the thickness “d2” of the island-shaped semiconductor layer 313 is set greater than the thickness “d1” (here, 50 nm) of the semiconductor layer 307, which will become the active region of TFT. More preferably, the thickness “d2” is set greater than the sum of the thickness “d3” (here, it is 100 nm) of the gate insulating film 309 and the thickness “d1” of the semiconductor layer 307 (here, the sum is 150 nm). Here, the thickness “d2” of the island-shaped semiconductor layer 313 is equal to the thickness of the second crystalline silicon film 310a, and it is 300 nm.

Next, as shown in FIG. 8(H), a mask 314 made of a resist is formed to cover a portion of the island-shaped semiconductor layer 313, which layer 313 will become the active region of the TFD later. Then, an n-type impurity (phosphorus) 315 is ion-doped into the entire surface from above the substrate 301. Phosphorus 315 is ion-doped into the island-shaped semiconductor layer 307, which is destined to become the active region of the TFT, through the gate insulating film 309. Phosphorus 315 is ion-doped into the island-shaped semiconductor layer 313, which is destined to become the active region of theTFD, directly (bare-doping). In this process, phosphorus 315 is implanted into the region in the island-shaped semiconductor layer 313 for the TFD that are not covered by the resist mask 314, and into the regions in the semiconductor layer 307 for TFT that are not covered by the semiconductor layer 312 (destined to become the gate electrode). Phosphorus 315 is implanted into the semiconductor layer 312 made of crystalline silicon (bare-doping) to form a gate electrode 317 composed of a crystalline silicon that is now n-type. Phosphorus 315 is not doped into resions of the semiconductor layers that are covered by the resist mask 314 or the gate electrode 317. This way, for the semiconductor layer 307 of the TFT, the regions into which the phosphorus 315 was implanted become source and drain regions 316 of the TFT, and the region into which the phosphorus 315 was not implanted because it was masked by the gate electrode 317 becomes a channel region 319 of the TFT. For the island-shaped semiconductor layer 313 for the TFD, the region into which the phosphorus 315 was implanted becomes the n⁺ region 318 of the TFD.

Here, the thickness “d1” of the semiconductor layer 307, the thickness “d2” of the semiconductor layer 313, and the thickness “d3” of the gate insulating film 309 satisfy the relationship d1+d3<d2. Therefore, even if the doping condition is optimized for the semiconductor layer 307, which is destined to become the active layer of the TFT to make the source and drain regions 316 low resistance, the impurity is not implanted relatively deep into the thickness “d2” of the semiconductor layer 313, which will become the active region of the TFD. Consequently, although this implantation is a bare-doping, the doping damage near the bottom layer of the semiconductor layer 313 can be suppressed to smaller than that of the semiconductor layer 307, which will become the active layer of the TFT. The gate electrode 317 is similar to the semiconductor layer 313, which is destined to become the active layer of the TFD. Therefore, although the implantation is bare-doping, the doping damage near the bottom surface of the gate electrode 317 is suppressed to smaller than that of the semiconductor layer 307, which is destined to become the active layer of the TFD.

Next, after the resist mask 314 used in the previous manufacturing step is removed, as shown in FIG. 8(I), a mask 320 made of a resist is formed to cover a portion of the island-shaped semiconductor layer 313, which layer 313 is destined to become the active region of the TFD, and to cover the entire island-shaped semiconductor layer 307, which is destined to become the active region of the TFT. Then, a p-type impurity (boron) 321 is ion-doped from above the substrate 301 into the entire surface. In this manufacturing step, boron 321 is implanted into a region in the island-shaped semiconductor layer 313 for the TFD that is not covered by the resist mask 320. Boron 32 is not doped into the region that is covered by the resist mask 320. By this impurity implantation, in the island-shaped semiconductor layer 313 for the TFD, the region into which the boron 321 was implanted becomes the p⁺ region 322 of TFD, and of the region into which the phosphorus was not implanted in the previous manufacturing step, the region into which the boron 321 was not implanted becomes the intrinsic region 323.

After the resist mask 320 used in the previous manufacturing step is removed, a heat treatment is conducted under an inert atmosphere, such as a nitrogen atmosphere. With this heat treatment, as shown in FIG. 8(J), the source and drain regions 316 of the TFT, n⁺ region 318 and p⁺ region 322 of the TFD, and the gate electrode 317 of the TFT recover from doping damages such as crystal defects that they suffered during the doping, and the phosphorus and boron doped into these regions are activated. Here, in the semiconductor layer 307 of the TFT, the semiconductor layer 313 of the TFD, and the gate electrode 317 of the TFT, which is the same layer as the semiconductor layer 313 of the TFT, the damage at the bottom surface of each of the semiconductor layers is suppressed. Therefore, recrystallization occurs starting from the bottom surface of the semiconductor layer, where the crystal destruction is minimal, towards the top surface. As a result, the crystalline state in the source and drain regions 316 of the TFT, the n⁺ region 318 and the p⁺ region 322 of TFD, and the gate electrode 317 of TFT is restored, thereby making these regions low resistance.

Furthermore, in this heat treatment, the phosphorus doped into the source and drain regions 316 of the semiconductor layer 307 of the TFT increases the solid solubility of nickel in the regions 316. The nickel present in the channel region 319 is therefore transferred from the channel region 319 to the source and drain regions 316 in the direction indicated by the arrows 324. As a result, the nickel moves into the source and drain regions 316 of the TFT, increasing the nickel concentration in the regions 316 beyond the nickel concentration in the channel region 319 to 1×10¹⁸/cm³ or higher. In the semiconductor layer 313 of the TFD, the phosphorus doped into the n⁺ region 318 increases the solid solubility of nickel in the region 318, and therefore the nickel present in the intrinsic region 323 is transferred from the intrinsic region 323 to the n⁺ region 318 in the direction indicated by the arrows 325. As a result, the nickel moves into the n⁺ region 318 of the TFD, raising the nickel concentration in these regions beyond the nickel concentration in the intrinsic region 323 to 1×10¹⁸/cm³ or higher.

Next, as shown in FIG. 8(K), interlayer insulating films 326 and 327 are formed. In this embodiment, an interlayer insulating film having a two-layer structure composed of a silicon nitride film 326 and a silicon oxide film 327 is formed. After the interlayer insulating film is formed, annealing is conducted at 350 to 450° C. under 1 atm of nitrogen atmosphere or hydrogen mixture atmosphere to hydrogenize the semiconductor layer 307 of the TFT and the semiconductor layer 313 of the TFD to reduce the crystal defects. Here, if the silicon nitride film 326 is formed to include hydrogens, those hydrogens in the silicon nitride film 326 can be utilized for this purpose, which improves efficiency.

Next, contact holes are formed in the silicon nitride film 326 and silicon oxide film 327, which are the interlayer insulating films, and electrodes/wirings 328 for the TFT and electrodes/wirings 329 for the TFD are formed using a metal material. This completes a thin film transistor 330 and a thin film diode 331. A protective film made of a silicon nitride film or the like may be provided over the thin film transistor 330 and the thin film diode 331 to protect these elements, as necessary.

According to the method described above, semiconductor layers for the TFT and the TFD, in particular, the channel region of the TFT and the intrinsic region of an optical sensor TFD, can be made separately. As a result, respective optimum element characteristics required for the TFT and for the optical sensor TFD can simultaneously be obtained. Also, in this embodiment, the light-shielding layer for the TFD is formed of the semiconductor film that is identical to the semiconductor film of the TFT, and the gate insulating film of the TFT is formed of the semiconductor layer identical to the semiconductor layer of the TFD. This simplifies the manufacturing process and reduces the manufacturing cost.

### Embodiment 4

Embodiment 4 of the semiconductor device according to the present invention is described below. Here, the embodiment is described in detail using an example of forming a pixel TFT for display and its auxiliary capacitance (capacitor), a CMOS structured TFT circuit for driving, and a photo sensor TFD on a glass substrate simultaneously. The semiconductor device of this embodiment can be used in active matrix type liquid crystal display devices with a built-in optical sensor, organic EL display devices and the like.

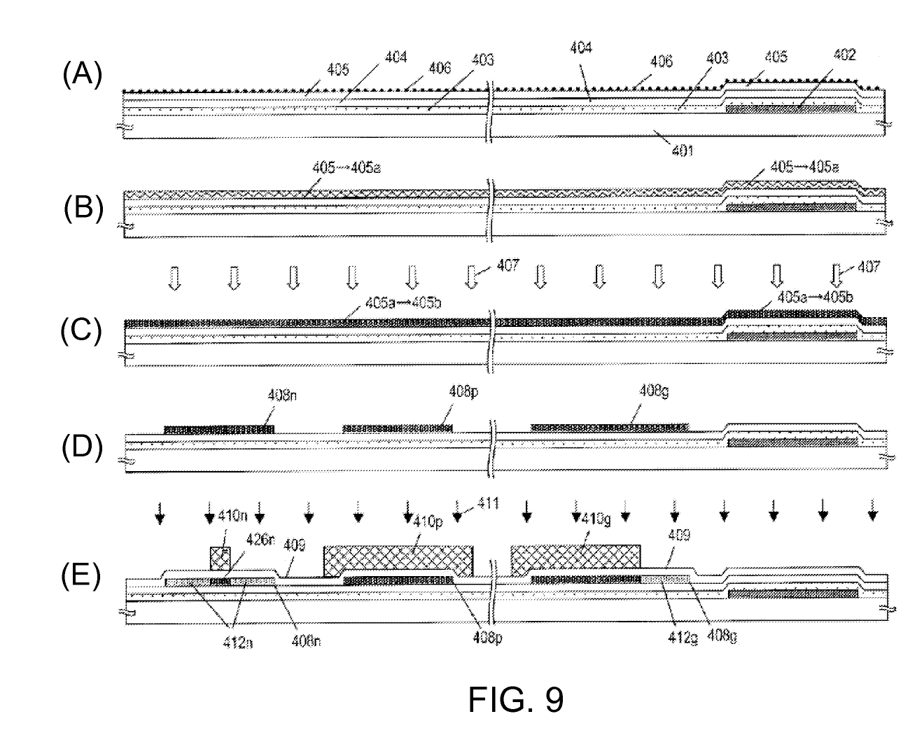

FIG. 9 through FIG. 11 are cross-sectional views illustrating the manufacturing steps for an n-channel type thin film transistor 431 and a p-channel type thin film transistor 432 for a driver circuit, an n-channel type thin film transistor 433 for driving a pixel electrode and a auxiliary capacitance 434 connected to the n-channel type thin film transistor 433 for driving a pixel electrode, and a thin film diode 435 for an optical sensor. The manufacturing steps proceed sequentially from FIG. 9(A) to FIG. 11(K).

First, as shown in FIG. 9(A), on the surface of a glass substrate 401 on which TFTs and a TFD are to be formed, a light-shielding layer 402 for the TFD for blocking light from the back of the substrate is formed. The light-shielding layer 402 may be a metal film or a silicon film. In this embodiment, a molybdenum (Mo) film is formed by sputtering and then patterned to form the light-shielding layer 402. Preferably, the thickness of the light-shielding layer 402 is set to 30 to 300 nm, and more preferably, it is set to 50 to 200 nm. In this embodiment, the thickness of the light-shielding layer 402 is set to 100 nm, for an example.

Next, on the glass substrate 401 and the light-shielding layer 402, base films 403 and 404, which may be a silicon oxide film, silicon nitride film, silicon nitride oxide film, or the like, and an amorphous semiconductor film 405 are formed in this order by the plasma CVD, for example.

Base films 403 and 404 are provided to prevent the impurity diffusion from the glass substrate. In this embodiment, a silicon nitride film having a thickness of about 100 nm is formed as the first base film 403, which is the lower layer. Then, a silicon oxide film having a thickness of about 200 nm is formed as the second base film 404. As an amorphous semiconductor film 405, an intrinsic (I-type) amorphous silicon film (a-Si film) having a thickness of about 20 to 80 nm (40 nm, for example) is formed by the plasma CVD or like method.

Next, a catalytic element is added to the surface of the a-Si film 405. Here, nickel is used as the catalytic element. As in Embodiment 2 and Embodiment 3, the a-Si film 405 is coated with an aqueous solution containing 5 ppm in weight, for example, of nickel (nickel acetate aqueous solution) by a spin coating method to form a catalytic element contained layer 406. The catalytic element concentration on the surface of the a-Si film 405 is about 5×10¹² atoms/cm².

Subsequently, a heat treatment is conducted under an inert atmosphere, such as a nitrogen atmosphere. As the heat treatment, preferably an annealing is conducted at 550 to 620° C. for 30 minutes to 4 hours. In this embodiment, a heat treatment at 600° C. was conducted for an hour as an example. In this heat treatment, the nickel that has been added to the a-Si film 405 surface diffuses into the a-Si film 405, and silicidation occurs. Crystallization of the a-Si film 405 proceeds from the silicided portions as nuclei. In this way, as shown in FIG. 9(B), a crystalline silicon film 405a is obtained.

Next, as shown in FIG. 9(C), the crystalline silicon film 405a obtained by the heat treatment is irradiated with the laser light 407 for further recrystallization to form a crystalline silicon film 405b having improved crystallinity.

The laser light 407 can be an XeCl excimer laser (wavelength: 308 nm) or a KrF excimer laser (wavelength: 248 nm). The laser light 407 is formed to have a beam spot that appears as an elongated shape on the surface of the substrate 401. The entire substrate is irradiated by the sequential scanning in the direction perpendicular to the direction of the longer side of the beam spot shape. If the scanning is conducted such that beams partially overlap one another, the laser is radiated multiple times into a given point on the crystalline silicon film 405a, thereby a highly uniform recrystallization can be performed. In this embodiment, the laser beam is formed to have a beam spot that appears as an elongated shape of 300 mm×0.4 mm on the surface of the substrate 401, and the scanning is conducted sequentially in the direction perpendicular to the direction of the longer side of the beam spot with a step interval of 0.02 mm. That is, at any given point on the silicon film, the laser is radiated 20 times in total. Here, YAG laser, YVO₄ laser, or the like can also be used as well as the aforementioned KrF excimer laser and XeCl excimer laser, which are a pulse oscillation type or a continuous light-emitting type.

Subsequently, unnecessary regions of the crystalline silicon region 405b are removed for device separation. As shown in FIG. 9(D), this process provides an island-shaped semiconductor layer 408n, which is destined to become the active region (the source and drain regions and the channel region) of an n-channel type TFT, and an island-shaped semiconductor layer 408p, which is destined to become the active region (the source and drain regions and the channel region) of a p-channel type TFT, both of which are to constitute a driver circuit section, and an island-shaped semiconductor layer 408g, which is destined to become the active region (the source and drain regions and the channel region) of the n-channel type TFT for driving the pixel electrode and also become the lower electrode of the auxiliary capacitance connected to the n-channel type TFT for driving the pixel electrode.

Here, although not illustrated, boron (B), a p-type impurity element, may be doped into all or a portion of the semiconductor layers to control the threshold voltage, with a concentration of about 1×10¹⁶ to 5×10¹⁷/cm³. Boron (B) may be ion-doped, or may be doped when the amorphous silicon film is formed.

Next, as shown in FIG. 9 (E), a gate insulating film 409 is formed to cover the semiconductor layers 408n, 408p, and 408g. Then, resist masks 410n, 410p, and 410g are formed of a photoresist. Next, a low-concentration impurity (phosphorus) 411 is implanted into the island-shaped semiconductor layers 408n and 408g using the resist masks 410n, 410p, and 410g as a mask.

In this embodiment, a silicon oxide film having a thickness of 20 to 150 nm (here, it is 70 nm) is formed as the gate insulating film 409. The silicon oxide film may also be formed of TEOS (Tetra Ethoxy Ortho Silicate) by decomposition and deposition with the RF plasma CVD method using oxygen at a substrate temperature of 150 to 600° C., or preferably 300 to 450° C. Alternatively, the silicon oxide film may be formed of TEOS through deposition by the low pressure CVD or atmospheric pressure CVD using an ozone gas at a substrate temperature of 350 to 600° C., or preferably 400 to 550° C. Also, once the silicon oxide film is formed, the silicon oxide film may be subjected to annealing for 1 to 4 hours under an inert gas atmosphere at 500 to 600° C. to improve the bulk property of the gate insulating film 409 and the property of the interface between the crystalline silicon films and the gate insulating film. As the gate insulating film 409, other insulating films containing silicon may be used. The gate insulating film 409 may have a single-layered or multiple-layered structure.

The resist masks 410n, 410p, and 410g are provided on the island-shaped semiconductor layers 408n, 408p, and 408g, respectively. For the semiconductor layer 408n, which is destined to become the active region of the n-channel type TFT, the resist mask 410n is provided to cover only the central portion that is destined to become the channel region. The end portions, which are destined to become the source and channel regions, remain uncovered. For the semiconductor layer 408g, which is destined to become the active region of the pixel TFT and the lower electrode of the auxiliary capacitance, the resist mask 410g is provided to cover only the portion that is destined to become the active region of the pixel TFT. The portion that is destined to become the lower electrode of the auxiliary capacitance remains uncovered. The resist mask 410p is provided to cover the entire semiconductor layer 408p, which is destined to become the active region of the p-channel type TFT.

The impurity (phosphorus) 411 can be implanted by the ion-doping method. Phosphine (PH₃) is used as a doping gas; the accelerating voltage is set to 60 to 90 kV (70 kV, for example); and the dose is set to 5×10¹² to 5×10¹⁴ cm⁻² (5×10¹³ cm⁻², for example). In this manufacturing step, a low concentration phosphorus 411 is implanted into the regions of the island-shaped semiconductor layers 408n and 408g that are not covered by the resist mask 410n or 410g, to make these regions the low-concentration n-type impurity regions 412n and 412g, respectively. The phosphorus 411 is not implanted into the regions covered by the resist mask 410n or 410g. The island-shaped semiconductor layer 408p is covered by the resist mask 410p, and therefore the phosphorus 411 is not implanted into the island-shaped semiconductor layer 408p at all.

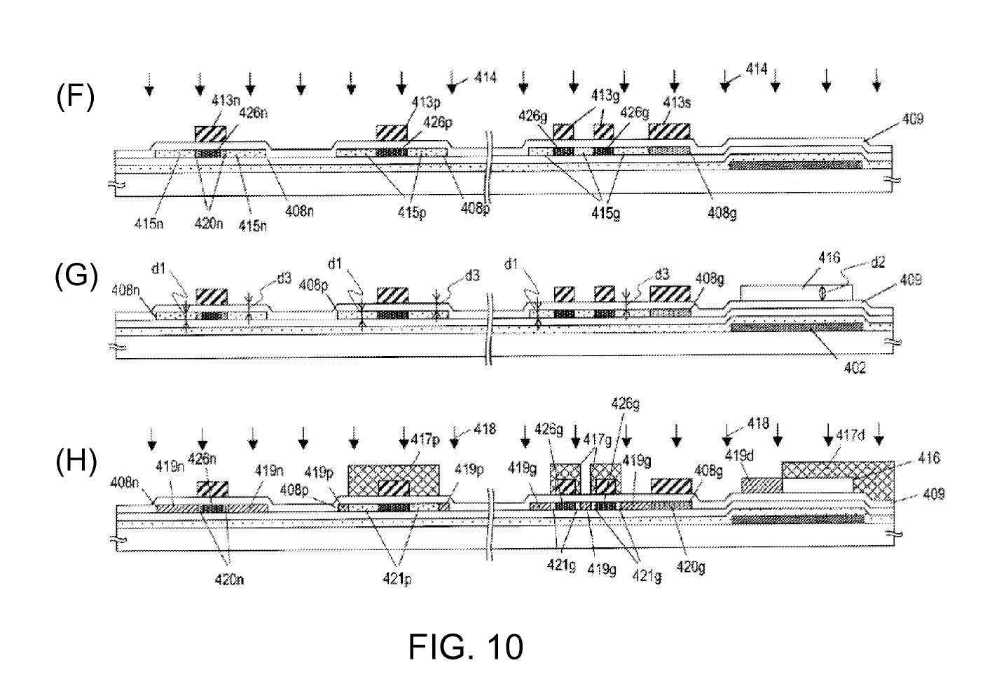

Next, as shown in FIG. 10(F), gate electrodes 413n, 413p, and 413g are formed on the island-shaped semiconductor layers 408n, 408p, and 408g, respectively, and an upper electrode 413s of the auxiliary capacitance is formed on the island-shaped semiconductor layer 408g. Then, using the ion-doping method, a second low-concentration impurity (phosphorus) 414 is implanted into the active region of each of the TFTs using the gate electrodes 413n, 413p, and 413g, and the upper electrode 413s of the auxiliary capacitance as masks.

Here, the gate electrode 413g of the pixel TFT to be formed later is divided into two parts to reduce the leakage current when the pixel TFT is off. This is to obtain a so-called dual gate structure where two TFTs are connected in series to each other. The gate structure of the pixel TFT may be a triple gate structure or a quad gate structure, where the number of gate electrode 413g (the number of TFTs connected in series) is increased.

The gate electrodes 413n, 413p, and 413g, and the upper electrode 413s of the auxiliary capacitance are formed by depositing a metal film by sputtering, which is then patterned. Materials of the metal film may be Al, Mo, Ta, W, Ti, or the like, or an alloy made of those elements. Materials that can be used are limited because of the heat treatment conducted later in the process. As other alternative materials, tungsten silicide, titan silicide, or molybdenum silicide may be used. In this embodiment, an Al—Ti alloy film (0.2%-3% of Ti included) having a thickness of 300 to 600 nm (450 nm, for example) is used.

In the phosphorus 414 implantation process, phosphine (PH₃) is used as the doping gas, the accelerating voltage is set to 60 to 90 kV (70 kV, for example), and the dose is set to 1×10¹² to 1×10¹⁴ cm⁻² (2×10¹³ cm⁻², for example). In this manufacturing step, the second low-concentration phosphorus 414 is implanted into the regions in the island-shaped semiconductor layers 408n, 408p, and 408g that are not covered by the gate electrode 413n, 413p, 413g, and the upper electrode 413s of the auxiliary capacitance. These regions become the second low-concentration n-type impurity regions 415n, 415p, and 415g. The phosphorus 414 is not implanted into the regions covered by the gate electrode 413n, 413p, 413g, and the upper electrode 413s of the auxiliary capacitance.

Subsequently, as shown in FIG. 10(G), a second crystalline silicon film is deposited on the gate insulating film 409 and then patterned to form an island-shaped semiconductor layer 416, which is destined to become the active region (n-type region, p-type region, intrinsic region) of a TFD.

The second crystalline silicon film is formed by the plasma CVD method using SiH₄ gas as a material at a substrate heating temperature of 300 to 450° C. Here, hydrogen is used as the diluent gas. By setting the hydrogen dilution ratio (SiH₄/H₂) to 1/50 or lower, the film acquires the crystal component when it is formed. For a higher crystallization rate, the dilution ratio should be higher. However, a high dilution ratio slows down the film formation. Therefore, the dilution ratio is preferably within a range of 1/50 to 1/1000. Ar gas may be added to the diluent gas. The pressure was set to 1 to 4 Torr (2.5 Torr, for example). RF power was set to 0.2 to 3 kW/m² (2 kW/m², for example). In this embodiment, the second crystalline silicon film is directly formed by depositing the crystalline silicon, and then patterning it with a known method to obtain a semiconductor layer 416.

In this embodiment, the semiconductor layer 416 is formed after the gate electrodes 413n, 413p, 413g, and 413s are formed. However, the semiconductor layer 416 may be formed prior to the formation of the gate electrodes.

Preferably, the thickness “d2” of the semiconductor layer 416 is set greater than the thickness “d1” (40 nm in this embodiment) of the semiconductor layers 408n, 408p, and 408g, which are destined to become the active regions of TFTs.

More preferably, the thickness “d2” of the island-shaped semiconductor layer 416 is greater than the sum of the thickness “d3” of the gate insulating film 409 and the thickness “d1” of any one of the semiconductor layers 408n, 408p, and 408g. In this embodiment, the thickness of the gate insulating film 409 immediately after the film is formed was 70 nm. However, when the gate electrodes 413n, 413p, and 413g are dry-etched, the regions of the gate insulating film 409 that are not covered by the gate electrode 413n, 413p, or 413g are overetched. As a result, the thickness “d3” of the regions of the gate insulating film 409 that are not covered by the gate electrode 413n, 413p, or 413g is about 55 nm, for example, which is smaller than the thickness right after the film formation by about 15 nm. Therefore, in this embodiment, preferably the thickness “d2” of the island-shaped semiconductor layer 416 is set greater than the sum of the thickness “d3” (55 nm) and thickness “d1” (40 nm), where the sum is 95 nm. Here, the thickness “d2” is set to 300 nm, for example.

Next, as shown in FIG. 10(H), a doping mask 417g, which is made of a photoresist, is provided to cover the gate electrodes 413g of the pixel TFT to be formed later and to cover some extra area around the gate electrodes 413g. For the p-channel type TFT to be formed, doping mask 417p is provided to cover the gate electrode 413p plus a larger extra area around the gate electrode 413p, so that the outer end portions of the semiconductor layer 408p are exposed. For the optical sensor TFD to be formed, a doping mask 417d is provided such that a portion of the semiconductor layer 416 is exposed. Subsequently, impurity (phosphorus) 418 is implanted at high concentration by the ion-doping method into each of the semiconductor layers using the gate electrode 413n of the n-channel type TFT, the upper electrode 413s of the auxiliary capacitance, and resist masks 417p, 417g, and 417d as masks. Phosphine (PH₃) is used as the doping gas, and the accelerating voltage is set to 40 to 80 kV (60 kV, for example), and the dose is set to 1×10¹⁵ to 1×10¹⁶ cm⁻² (5×10¹⁵ cm⁻², for example).

In this manufacturing step, impurity (phosphorus) 418 is implanted at high concentration into the regions of the semiconductor layer 408n for the n-channel type TFT that are not covered by the gate electrode 413n to form the source and drain regions 419n of the n-channel type TFT by self-alignment with the gate electrode 413n. Of the region in the semiconductor layer 408n that was covered by the gate electrode 413n and therefore the high-concentration phosphorus 418 was not doped into, the regions into which the low-concentration phosphorus had been implanted in the previous manufacturing step become the LDD regions, which overlap the gate electrode 413n, that is, a so-called GOLD (Gate Overlapped Lightly Doped Drain) region 420n. The region under the gate electrode 413n, into which even the low-concentration phosphorus had not been implanted becomes the channel region 426n. With this configuration, the electric field concentration at the junction area between the channel region and the source and drain regions 419n can be relieved, and the hot carrier resistance can be improved dramatically, thereby significantly enhancing the reliability of the n-channel type TFT in the driver circuit.

For the semiconductor layer 408g of the pixel TFT, impurity (phosphorus) 418 is implanted at high concentration into the region that is not covered by the resist mask 417g to form the source and drain regions 419g of the pixel TFT (n-channel type). Also, of the region covered by the resist mask 417g and therefore the high-concentration phosphorus 418 was not doped into, the region into which the low-concentration phosphorus had been implanted in the previous manufacturing step becomes LDD regions 421g, and the region under the gate electrode 413g into which even the low-concentration phosphorus had not been implanted becomes the channel region 426g. By using such LDD structured TFT having an LDD region that is offset outside the gate electrode as the pixel TFT, the leakage current when the TFT is OFF can be significantly reduced.

For the semiconductor layer 408p of the p-channel type TFT, impurity (phosphorus) 418 is implanted at high concentration into the region that was not covered by the resist mask 417p, to form high-concentration n-type regions 419p. The region 421p, which was covered by the resist mask 417p and into which the low-concentration phosphorus 414 had been implanted, remains as it is. For the semiconductor layer 408 for the optical sensor TFD, impurity (phosphorus) 418 is implanted at high concentration into the region not covered by the resist mask 417d to form a high-concentration n-type region 419d.

Preferably, the in-film concentration of the n-type impurity element (phosphorus) 411 in the GOLD regions 420n of the n-channel type TFT is 5×10¹⁷ to 1×10¹⁹/cm³, and the in-film concentration of the n-type impurity element (phosphorus) 414 of the LDD regions 421g of pixel TFT is 1×10¹⁷ to 5×10¹⁸/cm³. With the concentration within this range, each of the regions 420n and 421g functions more effectively as a GOLD region or an LDD region.

The high concentration doping of the phosphorus 418 is conducted on the island-shaped semiconductor layer 408n for the n-channel type TFT and the island-shaped semiconductor layer 408g of the pixel TFT through the gate insulating film 409, and the doping is conducted directly (bare-doping) on the island-shaped semiconductor layer 416, which is destined to become the active region of the TFD. Here, the thickness “d1” of the semiconductor layers 408n and 408g, thickness “d2” of the semiconductor layer 416, and thickness “d3” of the region of the gate insulating film 409 that was not covered by the gate electrodes are set to satisfy the relationship d1+d3<d2. Therefore, the doping conditions are optimized for the semiconductor layers 408n and 408g of the TFT, thereby making the source and drain regions 419n and 419g low resistance. However, the impurity is not implanted relatively deep into depth “d2” of the semiconductor layer 416, which is destined to become the active layer of the TFD. For this reason, although the implantation is bare-doping, the doping damage near the bottom surface of the semiconductor layer 416 can be suppressed to smaller than that of the semiconductor layers 408n and 408g of the TFT.

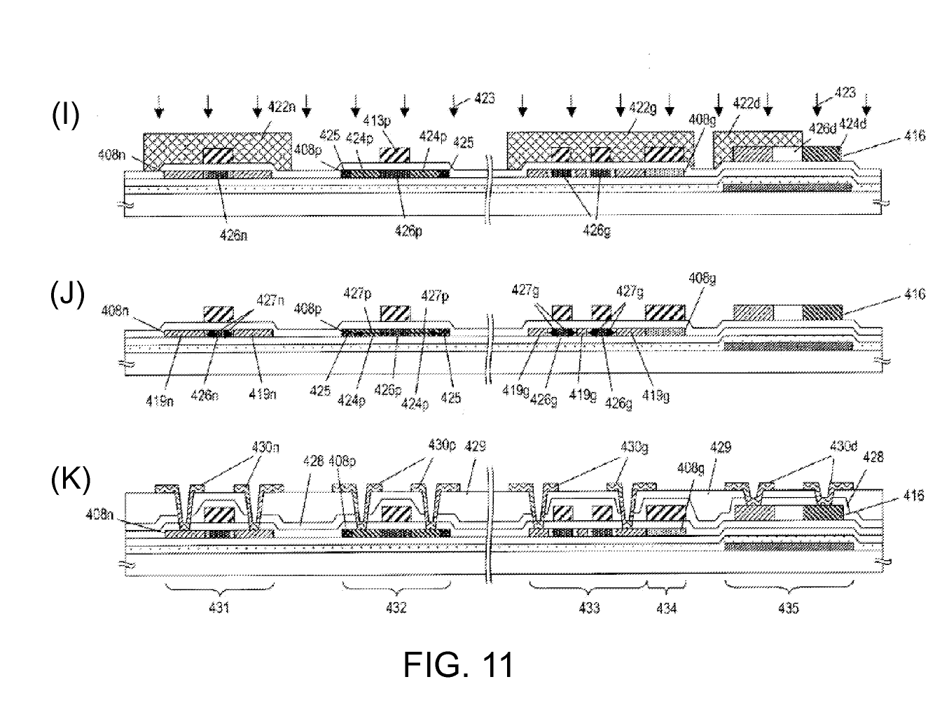

Next, as shown in FIG. 11(I), after the resist masks 417p, 417g, and 417d are removed, doping masks 422n, 422g, and 422d made of a photoresist is provided to cover the entire semiconductor layer 408n for the n-channel type TFT, the entire semiconductor layer 408g constituting the pixel TFT and its auxiliary capacitance, and to cover a portion of the semiconductor layer 416 for the TFD. Then, impurity (boron) 423, which is a p-type impurity, is implanted into the semiconductor layer 408p for the p-channel type TFT and the semiconductor layer 416 for the TFD with the ion doping method, using resist masks 422n, 422g, and 422d and the gate electrode 413p of the p-channel type TFT as masks. Here, diborane (B₂H₆) is used as a doping gas, and the accelerating voltage is set to 40 kV to 90 kV (70 kV, for example), and the dose is set to 1×10¹⁵ to 1×10¹⁶ cm⁻² (3×10¹⁵ cm⁻², for example).

In this manufacturing step, boron 423 is implanted at high concentration into regions of the semiconductor layer 408p for the p-channel type TFT that are not covered by the gate electrode 413p. Also, the regions 421p become p-type because phosphorus 414, which is an n-type impurity and was implanted into the regions 421p at low concentration in the previous manufacturing step, is reversed to form source and drain regions 424p of the TFT by self-alignment with the gate electrode 413p. Furthermore, in addition to the high-concentration phosphorus 418 implantation conducted in the previous manufacturing step, the regions 419p are subjected to high-concentration boron 423 implementation and become gettering regions 425. High-concentration boron 423 is not implanted into the region under the gate electrode 413p and that region becomes a channel region 426p.

For the semiconductor layer 416 for the optical sensor TFD, the region not covered by the resist mask 422d is subjected to the implantation of high-concentration boron 423, and becomes a p-type region 424d of the TFD. The region that was covered by the resist mask 422d and the resist mask 417d in the previous manufacturing step and therefore neither phosphorus nor boron was implanted into becomes an intrinsic region 426d of the TFD. In the manufacturing step described above, the semiconductor layer 408n of the n-channel type TFT and the semiconductor layer 408g destined to become the pixel TFT and the lower electrode of the auxiliary capacitance of the pixel TFT are covered entirely by the resist masks 422n and 422g, and therefore boron 423 is not doped into those semiconductor layers.

The high concentration doping of boron 423 is conducted on the island-shaped semiconductor layer 408p for the p-channel type TFT through the gate insulating film 409, and the doping is conducted directly (bare-doping) on the island-shaped semiconductor layer 416, which is destined to become the active region of the TFD. Here, thickness “d1” of the semiconductor layer 408p, thickness “d2” of the semiconductor layer 416, and thickness “d3” of the regions of the gate insulating film 409 that were not covered by the gate electrodes are set to satisfy the relationship d1+d3<d2. Therefore, the boron 423 doping conditions can be optimized for the semiconductor layer 408p of the TFT, thereby making the source and drain regions 424p low resistance. On the other hand, the impurity is not implanted relatively deep into depth “d2” of the semiconductor layer 416, which is to become the active layer of the TFD. As a result, although the implantation is bare-doping, the doping damage near the bottom surface of the semiconductor layer 416 can be suppressed to smaller than that of the semiconductor layer 408p of the TFT.

Next, after the resist masks 422n, 422g, and 422d are removed, a heat treatment is conducted under an inert atmosphere, such as a nitrogen atmosphere. In this embodiment, the RTA treatment is used, where each of the substrates is separately moved into the high temperature atmosphere and be subjected to a high temperature nitrogen gas spray for fast temperature raising/lowering. The treatment is conducted by raising or lowering the temperature with a temperature raising/lowering rate exceeding 200° C./min. As an example, heat treatment was conducted at 650° C. for 10 minutes. Other heat treatment system can also be used, and parameters can be set by users for their convenience. Of course, a general diffusion furnace (furnace) and lamp heating system RTA can also be used.

By this heat treatment, as shown in FIG. 11(J), for the semiconductor layer 408n for the n-channel type TFT and for the pixel switching thin film transistor 408g, the phosphorus doped into the source and drain regions 419n and 419g increases the solid solubility of nickel in the regions. The nickel present in the channel regions 426n and 426g, the GOLD regions 420n, and the LDD regions 421g is therefore transferred from the channel regions to the GOLD regions or LDD regions and to the source and drain regions in the directions indicated by the arrows 427n and 427g. Also, for the semiconductor layer 408p for the p-channel type TFT, highly concentrated phosphorus and boron that are doped into the gettering regions 425 formed outside the source and drain regions 424p and damages such as the lattice defects occurred during the boron doping cause the nickel present in the channel region 426p and in the source and drain regions 424p to move from the channel region to the source and drain regions and also to the gettering regions 425 in the directions indicated by the arrows 427p. Because of this heat treatment process, the nickel moves into the source and drain regions 419n and 419g of the n-channel type TFT and the pixel TFT, and to the gettering regions 425 of the p-channel type TFT. As a result, the nickel concentration in these regions increases to 1×10¹⁸/cm³ or higher.

In the heat treatment process, doping damages such as crystal defects, which was generated when n-type impurity (phosphorus) was doped into the source and drain regions 419n and 419g, GOLD region 420n, LDD region 421g, and the auxiliary capacitance lower electrode region 420g of the n-channel type TFT and the pixel TFT and into the n-type region 419d of the TFD, and doping damages generated when p-type impurity (boron) was doped into the source and drain regions 424p of the p-channel type TFT and the p-type region 424d of the TFD are recovered, and the phosphorus and boron doped into these regions are activated. As described above, for these semiconductor layers 408n, 408g, and 416, doping damages generated at the bottom surface of the semiconductor layers due to the high-concentration phosphorus 418 doping are suppressed by adjusting the thickness of each of the layers and doping conditions. Consequently, recrystallization occurs from the bottom surface where the crystal destruction is minimal, and as a result, a good crystalline state is restored in the source and drain regions 419n of the n-channel type TFT, the source and drain regions 419g of the pixel TFT, and the n⁺ region in the n-type region 419d of the TFD, and these regions are made low resistance. For the semiconductor layers 408p and 416, as described above, doping damages generated at the bottom surface of the semiconductor layers due to the high concentration boron 423 doping are also suppressed, and therefore, recrystallization occurs from the bottom surface where the crystal destruction is minimal. As a result, a good crystalline state is restored in the source and drain regions 424p of the p-channel type TFT and the p⁺ region in the p-type region 424d of the TFD, and the regions are made low resistance.

As a result, the sheet resistance of the source and drain regions of the n-channel type TFT and the pixel TFT is approximately 0.3 to 0.7 kΩ/□, and the sheet resistance of the n-type region of the TFD is approximately 0.5 to 1.0 kΩ/□. The sheet resistances of the GOLD regions and the auxiliary capacitance lower electrode region were approximately 20 to 60 kΩ/□, and the sheet resistance of the LDD regions was approximately 40 to 100 kΩ/□. The sheet resistance of the source and drain regions of the p-channel type TFT was approximately 0.7˜1.2 kΩ/□, and the sheet resistance of the p-type region of TFD was 1.0˜1.5 kΩ/□. In the gettering regions of the p-channel type TFT, phosphorus, which is an n-type impurity element that has been doped, and boron, which is the p-type impurity element that has been doped, cancel out their carriers (electrons and holes). This makes their sheet resistance to be several tens of kΩ/□, which is a nonfunctional value for the source and drain regions. However, in the semiconductor layer for the p-channel type TFT, the gettering regions are disposed such that they do not prevent the flow of the carriers, and thus they do not cause any operational issue.

Next, as shown in FIG. 11(K), interlayer insulating films 428 and 429 (thickness: 400 to 1500 nm; typically 600 to 1000 nm) are formed. As the interlayer insulting film, a silicon nitride film, silicon oxide film, or silicon nitride oxide film can be used. In this embodiment, the interlayer insulating films has a multi-layered structure including the silicon nitride film 428 having a thickness of 200 nm and the silicon oxide film 429 having a thickness of 700 nm. The silicon nitride film 428 can be formed by the plasma CVD method using SiH₄ and NH₃ as material gases. Silicon oxide film 429 can be formed by the plasma CVD method using TEOS and O₂ as the materials. Preferably, the silicon nitride film 428 and silicon oxide film 429 are formed continuously. Materials and formation methods for the interlayer insulating film are not limited to those described above. Other insulating films containing silicon may also be used. Also, the interlayer insulating film may be mono-layered or multi-layered. For the interlayer insulating film having a multi-layered structure, an organic insulating film such as acrylic film may be provided as the upper layer insulating film.

Subsequently, a heat treatment is conducted at 300 to 500° C. for about 30 minutes to several hours to hydrogenize the semiconductor layers. This is the process in which hydrogen atoms are supplied to the interface between the active regions and the gate insulating film to inactivate the dangling bonds, which deteriorate the TFT characteristics, by terminating them with hydrogen atoms. In this embodiment, under the nitrogen atmosphere containing approximately 3% hydrogen, a heat treatment was conducted at 400° C. for an hour. If the interlayer insulating film (in particular, the silicon nitride film 326) contains sufficient amount of hydrogen, a similar effect can be obtained by conducting a heat treatment in a nitrogen atmosphere. As another hydrogenation means, the plasma hydrogenation (hydrogen excited by the plasma is used) can be used.

Next, as shown in FIG. 11(K), contact holes are formed in the interlayer insulating films 428 and 429, and electrodes/wirings 430n, 430p, 430g, and 430d of TFTs are formed of two-layers of metal materials, such as titanium nitride and aluminum. The titanium nitride film is provided as a barrier film that prevents the aluminum from diffusing into the semiconductor layer. In this way, the n-channel type thin film transistor 431 and the p-channel type thin film transistor 432 for the driver, the thin film transistor 433 for pixel switching, and the auxiliary capacitance 434 connected to the thin film transistor 433 for pixel switching, and the thin film diode 435 for the optical sensor are obtained.

Although not illustrated, a transparent conductive film such as ITO is connected to one of the electrodes/wirings 430g of the thin film transistor 433 for pixel switching to form a pixel electrode. Also, contact holes are provided on the gate electrodes 413n and 413p as necessary to connect between the necessary electrodes via the wirings 430. Furthermore, a protective film such as a silicon nitride film may be provided over each of the TFTs to protect the TFTs.

The field effect mobility of the n-channel type thin film transistor manufactured with the method described above was 250 to 300 cm²/Vs, and the threshold voltage was about 1 V. The field effect mobility of the p-channel type thin film transistor 432 was 120 to 150 cm²/Vs, and the threshold voltage was about −1.5 V. These results indicate favorable TFT characteristics. Circuits such as inverters chain and ring oscillators formed of CMOS structured circuits, where the n-channel type thin film transistor 431 and the p-channel type thin film transistor 432 are configured in a complementary fashion, presented a higher reliability and exhibited more stable circuit characteristics than conventional circuits. Furthermore, compared to the case where the same semiconductor layer is used both for the thin film diode and the thin film transistor, the thin film diode 435 as an optical sensor element presented a significantly improved light/dark ratio. As described above, it was confirmed that by making semiconductor layers separately for each of the elements, the characteristics of each device can be optimized.

As described above, this embodiment can suitably be applied not only to liquid crystal display devices, but also to organic EL display devices, for example. For example, a bottom emission-type organic EL display device can be manufactured by forming a transparent electrode layer, a light emitting layer, and an upper electrode layer in this order with the method described above on a substrate on which thin film transistors and thin film diodes are provided. Alternatively, as the upper electrode layer, a transparent electrode may be formed to manufacture a top emission-type organic EL display device. In that case, the substrate does not have to be light-transmissive.

The structure and manufacturing method of the semiconductor device according to this embodiment are not limited to the above. According to the method described with reference to FIG. 9 to FIG. 11, the light-shielding layer for the TFD, the semiconductor layer for the TFT, the semiconductor layer of the TFD, and the gate electrode of the TFT are formed of different films, respectively. However, as described in Embodiment 3, the light-shielding layer and semiconductor layer for the TFT may be formed of the same crystalline semiconductor film, and the gate electrode and the semiconductor layer for the TFD may be formed of the same crystalline semiconductor film. Also, the method of forming the crystalline semiconductor film for forming the semiconductor layer for the TFT is not limited to the method in which catalytic element is used to crystallize the amorphous semiconductor film. For example, as described in Embodiment 1, amorphous semiconductor film may be crystallized by laser radiation. Furthermore, the method of forming the crystalline semiconductor film for forming the semiconductor layer for the TFD is not limited to the plasma CVD. The amorphous semiconductor film may be crystallized using a catalytic element, or by laser radiation.

### Embodiment 5

In this embodiment, display devices equipped with a sensor feature are described. These display devices are configured using semiconductor devices of any one of the embodiments described above.

Display devices having a sensor feature of this embodiment are, for example, liquid crystal display devices equipped with a touch sensor, and have a display region and a frame region surrounding the display region. The display region includes a plurality of display sections (pixels) and a plurality of optical sensor sections. Each display section has a pixel electrode and a pixel switching TFT, and each optical sensor section has a TFD. A display driver circuit for driving individual display section is provided in the frame region. The driver circuit uses driver circuit TFTs. The pixel switching TFTs, the driver circuit TFTs, and the optical sensor TFDs are formed on a single substrate by the method as described in the Embodiments 1 to 4. Here, in a display device of the present invention, at least the pixel switching TFT, among all TFTs used in the display device, needs to be formed on the same substrate as the optical sensor section TFD by the method described above. The driver circuit, for example, may be provided on a separate substrate.

In this embodiment, the optical sensor section is disposed adjacent to the corresponding display section (a primary color pixel, for example). For one display section, one optical sensor section or a plurality of optical sensor sections may be provided. Alternatively, one optical sensor section may be provided for a set of display sections. For example, one optical sensor section may be provided for a color display pixel composed of three primary color (RGB) pixels. In this way, the number of optical sensor sections (density) versus the number of display sections can be appropriately selected according to the resolution.

A color filter provided in the optical sensor section on the viewer's side can lower the sensitivity of the TFDs constituting the optical sensor sections. Therefore, preferably no color filter is provided at the optical sensor section on viewer's side.

The configuration of the display device according to this embodiment is not limited to the above. For example, a display device equipped with an ambient light sensor in which an optical sensor TFD is disposed in the frame region to control the display brightness according to the brightness of the ambient light can be configured. Also, the optical sensor section can be used as a color image sensor by disposing a color filter at the optical sensor section on viewer's side so that the optical sensor section receives the light coming through the color filter.

Below, the configuration of a display device according to this embodiment is described with reference to figures, using a touchscreen liquid crystal display device equipped with touchscreen sensors as an example.

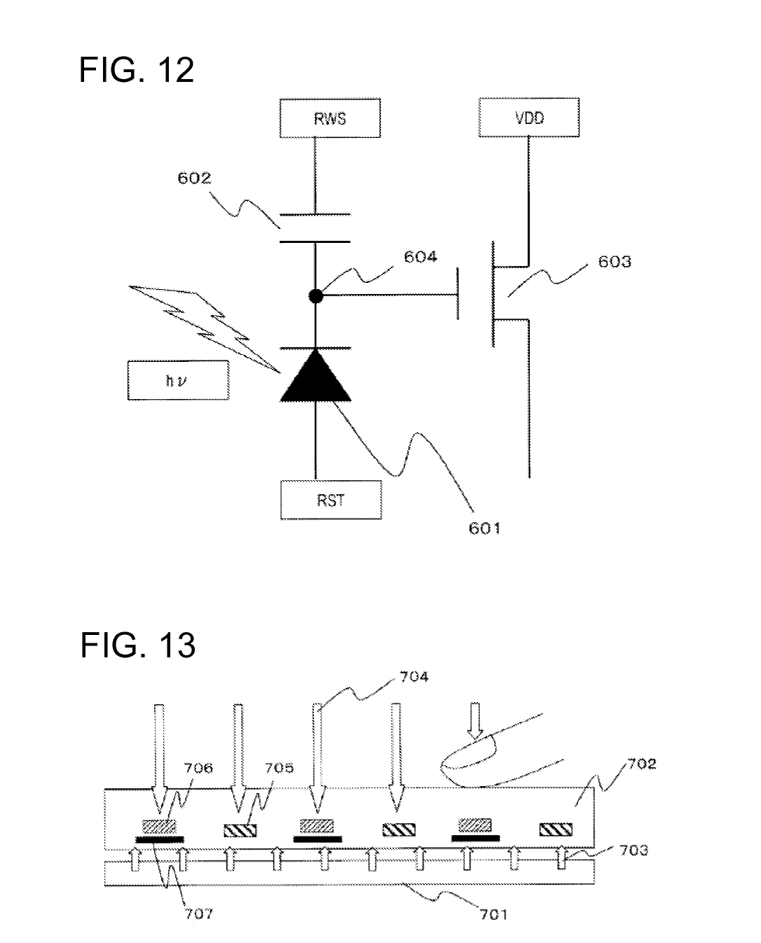

FIG. 12 is a circuit diagram showing an example of the configuration of the optical sensor section disposed in the display region. The optical sensor section includes an optical sensor thin film diode 601, a capacitor 602 for signal storage, and a thin film transistor 603 for retrieving signals stored in the capacitor 602. After RST signal is input and RST potential is written on node 604, when the electrical potential at node 604 lowers because of the leakage due to the light, the gate potential of the thin film transistor 603 changes and the TFT gate is turned on/off. Signal VDD can be extracted in this way.

FIG. 13 is a schematic cross-sectional view illustrating an example of the active matrix type touchscreen liquid crystal display device. In this example, one photo touch sensor section including an optical sensor section is provided for each pixel.

The liquid crystal display device illustrated here includes a liquid crystal module 702 and a backlight 701 disposed at the rear side of the liquid crystal module 702. Although not illustrated in the figure, the liquid crystal module 702 is composed of, for example, a light-transmissive rear substrate, a front substrate, which is disposed opposite to the rear substrate, and a liquid crystal layer interposed between these substrates. The liquid crystal module 702 has a plurality of display sections (primary color pixels), and each display section includes a pixel electrode (not shown) and a pixel switching thin film transistor 705 connected to the pixel electrode. Also, a photo touch sensor section that includes a thin film diode 706 is disposed adjacent to each display section. Although not shown in the figure, a color filter is disposed for each display section on the viewer's side, but no color filter is disposed for the photo touch sensor section on the viewer's side. A light-shielding layer 707 is interposed between the thin film diode 706 and the backlight 701. The light from the backlight701 is blocked by the light-shielding layer 707 and therefore does not enter the thin film diode 706; only external light 704 enters the thin film diode 706. The entry of the external light 704 is detected by the thin film diode 706, and therefore the light-sensing touchscreen is realized. The light-shielding layer 707 need to be disposed at least to block the light emitted by the backlight 701 from entering the intrinsic region of the thin film diode 706.

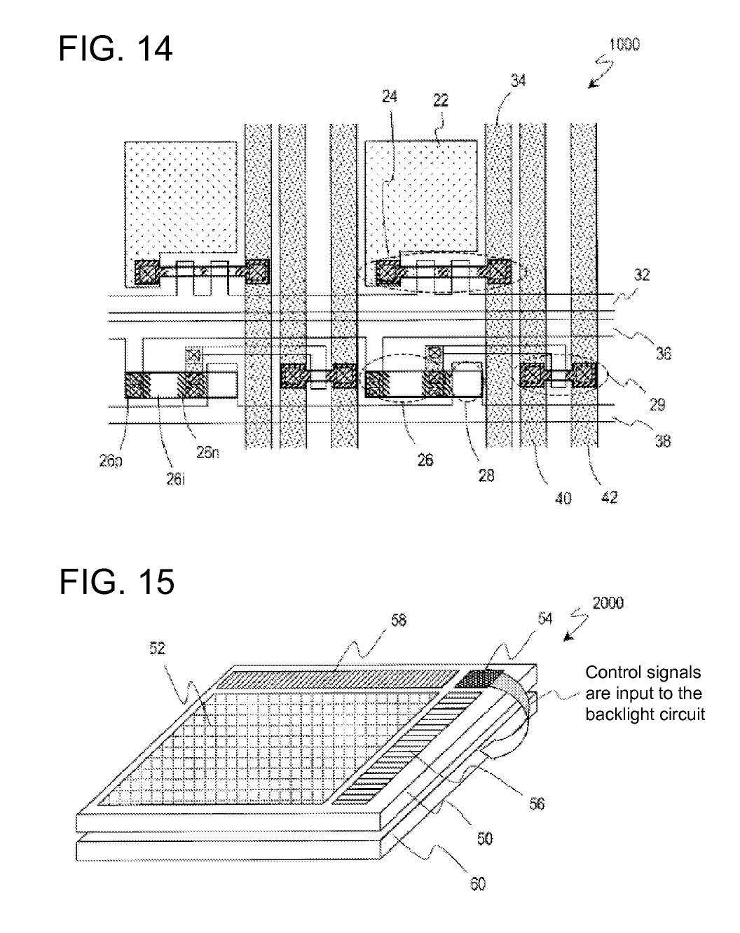

FIG. 14 is a schematic plan view illustrating an example of the rear substrate in an active matrix type touchscreen liquid crystal display device. Although the liquid crystal display device of this embodiment is composed of a large number of pixels (R, G, B pixels), only two pixels are shown here for simplification.

Rear substrate 1000 includes a plurality of display sections (pixels), each of which having a pixel electrode 22 and a pixel switching thin film transistor 24, and a photo touch sensor section disposed adjacent to the each display section and including an optical sensor photodiode 26, a signal storage capacitor 28, and a follower thin film transistor 29 for the optical sensor.

The thin film transistor 24 has a configuration similar to that of the pixel switching TFT as described in Embodiment 4, for example. This is a dual gate LDD structure, which includes two gate electrodes and LDD regions. The source region of the thin film transistor 24 is connected to the source bus line 34 for pixels, and the drain region is connected to the pixel electrode 22. The thin film transistor 24 is turned on/off according to the signal from the gate bus line 32 for pixels. Accordingly, voltages are applied on the liquid crystal layer by the pixel electrode 22 and the opposite electrode, which is formed on the front substrate disposed opposite to the rear substrate 1000, to change the orientation of the liquid crystal layer to perform a display.

On the other hand, optical sensor photo diode 26 has a configuration similar to, for example, the TFD described in Embodiment 4, which includes a p⁺-type region 26p, an n⁺-type region 26n, and an intrinsic region 26i interposed between the regions 26p and 26n. The signal storage capacitor 28 forms a capacitance with the gate insulating film, using the gate electrode layer and the Si layer as the electrodes. The p⁺-type region 26p of the optical sensor photodiode 26 is connected to the RST signal line 36 for the optical sensor, and the n⁺-type region 26n is connected to the lower electrode (Si layer) of the signal storage capacitor 28, and, through this capacitor 28, connected to the RWS signal line 38. Further, the n⁺-type region 26n is connected to the gate electrode layer of the follower thin film transistor 29 for the optical sensor. The source and drain regions of the follower thin film transistor 29 for the optical sensor are connected to the VDD signal line 40 for the optical sensor and the COL signal line 42 for optical sensor, respectively.

As described above, the optical sensor photodiode 26, signal storage capacitor 28, and the follower thin film transistor 29 for the optical sensor correspond respectively to the driver circuit thin film diode 601, the capacitor 602, and the thin film transistor 603 shown in FIG. 12, thereby constituting the driver circuit of the optical sensor. The light detecting operation of this driver circuit is described below.

(1) First, RWS signal is written on the signal storage capacitor 28 by the RWS signal line 38. This generates a positive electric field for the optical sensor photodiode 26 on the n⁺-type region 26n side, which makes the optical sensor photodiode 26 reverse biased. (2) In the optical sensor photodiode 26 located in a region of the substrate surface that is exposed to the light, the light leakage occurs to release the electrical changes to the side of the RST signal line 36. (3) As a result, the electrical potential on the side of the n⁺-type region 26n lowers. According to this change in the potential, the gate voltage applied to the follower thin film transistor 29 for optical sensor changes. (4) On the source side of the follower thin film transistor 29 for the optical sensor, the VDD signal from the VDD signal line 40 is applied. When the gate voltage changes as described above, the current that flows into the COL signal line 42 connected to the drain side changes. Consequently, the electrical signals can be retrieved from the COL signal line 42. (5) RST signals from the COL signal line 42 are written on the optical sensor photodiode 26 to reset the potential of the signal storage capacitor 28. The light sensing is possible by repeating the above operations (1) to (5) in a scanning manner.

The configuration of the rear substrate of the touchscreen liquid crystal display device of this embodiment is not limited to the configuration illustrated in FIG. 14. For example, the auxiliary capacitance (Cs) may be provided for each pixel switching TFT. Also, in the example illustrated in the figure, a photo touch sensor section is provided adjacent to each of the RGB pixels. However, as discussed above, one photo touch sensor section may be provided for a set of three RGB pixels (color display pixels).

Here, FIG. 13 is referenced again. As shown in the cross-sectional view in FIG. 13, the thin film diode 706 is disposed in the display region to be used as a touch sensor in the example discussed above. However, the thin film diode 706 can also be formed outside the display region so as to be used as an ambient light sensor for controlling the luminance of the backlight 701 according to the brightness of the external light 704.

FIG. 15 is a perspective view illustrating an example of the liquid crystal display device equipped with an ambient light sensor. A liquid crystal display device 2000 includes a display region 52, a gate driver 56, a source driver 58, and an LCD substrate 50 equipped with an optical sensor section 54, and a backlight 60 disposed at the back side of the LCD substrate 50. The region of the LCD substrate 50 that is in the periphery of the display region 52 and where drivers 56 and 58 and the optical sensor section 54 are provided is sometimes called “frame region.”

The luminance of the backlight 60 is controlled by a backlight control circuit (not shown). Although not shown in the figure, TFTs are used in the display region 52 and in the drivers 56 and 58, and TFDs are used in the optical sensor section 54. The optical sensor section 54 generates illuminance signals according to the brightness of the external light, and the signals are input to the backlight control circuit through the connection via flexible substrates. The backlight control circuit generates the backlight control signals based on the illuminance signals, and outputs the control signals to the backlight 60.

The present invention can be used to provide an organic EL display device equipped with an ambient light sensor. Such organic EL display device can have a configuration where a display section and an optical sensor section are disposed on a single substrate, as in the case of the liquid crystal display device shown in FIG. 15, but the backlight 60 does not need to be provided at the back side of the substrate. In this case, optical sensor section 54 is connected to the source driver 58 via the wiring provided on the substrate 50, and the illuminance signals from the optical sensor section 54 are input to the source driver 58. The source driver 58 changes the luminance of the display section 52 according to the illuminance signals.

Specific embodiments of the present invention have been described above. However, the present invention is not limited to the embodiments described above, and various changes can be made within the spirit of the present invention. Using the TFTs of the present invention, a circuit for conducting the analog drive and a circuit for conducting the digital drive can be configured simultaneously on a glass substrate. For example, the circuit for the analog drive includes a source side driver circuit and a driver circuit for gate driver and pixels. The source side driver circuit has a shift register, a buffer, and a sampling circuit (transfer gate), and the gate side driver circuit has a shift register, a level shifter, and a buffer. If necessary, a level shifter circuit may be provided between the sampling circuit and the shift register. By following the manufacturing steps of the present invention, memories and microprocessors can also be formed.

According to the present invention, a semiconductor device having a TFT and a TFD provided on a single substrate can be obtained, where both the TFT and the TFD are made of semiconductor films optimized for respective semiconductor elements and having desired characteristics. Therefore, TFTs having a high field effect mobility and a high on/off ratio, which are used for driver circuits and pixel electrode switching, and TFDs having a high S/N ratio against the light (the ratio of the electrical current when the light is present and when the light is not present) for an optical sensor can be manufactured in the same manufacturing process. Among these semiconductor layers, by optimizing the thickness and crystalline state of, in particular, the channel region of the TFTs, the region that significantly affects the field effect mobility of TFT, and those of the intrinsic region of TFDs, the region that significantly influence the light sensitivity of the TFD, characteristics that are optimum for the respective semiconductor elements can be realized. Furthermore, in addition to product size reduction and improvement in performance, the present invention provides a benefit that such high-performance semiconductor devices can be manufactured in a simple manner, and helps reduce the production cost.

### INDUSTRIAL APPLICABILITY

The present invention is widely applicable to semiconductor devices equipped with TFTs and TFDs, and to all kinds of electronic devices having such semiconductor devices. For example, the present invention can be applied to CMOS circuits and pixel sections of active matrix liquid crystal display devices and organic EL display devices. These display devices can be utilized for portable phones, displays of portable game machines, monitors of digital cameras, and the like. Therefore, the present invention can be applicable to all the electronic devices that have built-in liquid crystal display devices or organic EL display devices.

The present invention can suitably be used for, in particular, display devices such as active matrix type liquid crystal display devices and organic EL display devices, image sensors, optical sensors, and electronic devices that are the combination of such display devices. It is advantageous to utilize the present invention for, in particular, display devices having optical sensor features using TFDs or electronic devices equipped with such display devices. The present invention can be applicable to image sensors equipped with an optical sensor using TFDs and a driver circuit using TFTs.

### DESCRIPTION OF REFERENCE CHARACTERS

100 semiconductor device
101, 201 substrate
102, 202 light-shielding layer
103, 104, 203, 204 base film
105, 205 amorphous semiconductor film (for TFT)
105c, 205a crystalline semiconductor film
107, 208 semiconductor layer for thin film transistor (crystalline semiconductor layer)
110, 212 semiconductor layer for thin film diode (crystalline semiconductor layer)
108, 209 gate insulating film
109, 216 gate electrode
113, 215 source and drain regions
115, 218 channel region
114, 217 n-type region
118, 221 p-type region
119, 222 intrinsic region
120, 121, 130, 224, 225 interlayer insulating film
122, 123, 226, 227 electrode wiring
124, 228 thin film transistor
125, 229 thin film diode

1. A semiconductor device comprising:
a substrate;
a thin film transistor supported by said substrate, a first crystalline semiconductor layer including a channel region and source and drain regions, a gate insulating film disposed to cover said first crystalline semiconductor layer, and a gate electrode disposed on said gate insulating film to control a conductivity of said channel region; and
a thin film diode supported by said substrate, including a second crystalline semiconductor layer including at least an n-type region and a p-type region,
wherein said second crystalline semiconductor layer is formed on said gate insulating film in contact with a surface of said gate insulating film, and
wherein said n-type region or said p-type region and said source and drain regions contain an identical impurity element.

2. The semiconductor device according to claim 1, wherein thickness d2 of said second crystalline semiconductor layer is greater than thickness d1 of said first crystalline semiconductor layer.

3. The semiconductor device according to claim 1,
wherein said thin film transistor further comprises an interlayer insulating layer in contact with a top surface of said gate electrode,
wherein said thin film diode further comprises an interlayer insulating layer in contact with a top surface of said second crystalline semiconductor layer, and
wherein said interlayer insulating layer of said thin film transistor and said interlayer insulating layer of said thin film diode are formed of an identical insulating film.

4. The semiconductor device according to claim 1, wherein depth Dd from a top surface of said n-type region or said p-type region to a peak of a concentration profile of said identical impurity element in said n-type region or said p-type region in a direction of thickness and depth Dt from a top surface of said gate insulating film to a peak of a concentration profile of said identical impurity element in said source and drain regions in a direction of thickness are substantially the same.

5. The semiconductor device according to claim 1, wherein thickness d2 of said second crystalline semiconductor layer is greater than a sum (d1+d3) of thickness d1 of said first crystalline semiconductor layer and thickness d3 of said gate insulating film.

6. The semiconductor device according to claim 1, wherein a concentration profile of said identical impurity element in said n-type region or said p-type region in a direction of thickness has a peak in said second crystalline semiconductor layer.

7. The semiconductor device according to claim 1, wherein a concentration profile of said identical impurity element in said source and drain regions in a direction of thickness has a peak between a top surface of said gate insulating film and a bottom surface of said first crystalline semiconductor layer.

8. The semiconductor device according to claim 1, wherein the concentration profile of said identical impurity element in said source and drain regions in a direction of thickness has a peak in said first crystalline semiconductor layer.

9. The semiconductor device according to claim 5, wherein thickness d3 of said gate insulating film is the thickness of said gate insulating film over the source and drain regions of said first crystalline semiconductor layer.

10. The semiconductor device according to claim 1, wherein said second crystalline semiconductor layer includes an intrinsic region interposed between the n-type region and the p-type region.

11. The semiconductor device according to claim 1, wherein said gate electrode is formed of a semiconductor film identical to that of which said second crystalline semiconductor layer is formed.

12. The semiconductor device according to claim 1, wherein said substrate is light-transmissive, and the semiconductor device further comprises a light-shielding layer interposed between said second crystalline semiconductor layer and said substrate.

13. The semiconductor device according to claim 12, wherein said light-shielding layer is formed of a semiconductor film identical to that of which said first crystalline semiconductor layer is formed.

14. A method for manufacturing a semiconductor device comprising the steps of:
(a) preparing a substrate having a first crystalline semiconductor film formed thereon;
(b) forming a first island-shaped semiconductor layer that will become an active region of a thin film transistor by using a portion of said first crystalline semiconductor film;
(c) forming a gate insulating film over said first island-shaped semiconductor layer;
(d) forming a second crystalline semiconductor film on said gate insulating film in contact with a surface of said gate insulating film; and
(e) forming a second island-shaped semiconductor layer that will become an active region of a thin film diode by using a portion of said second crystalline semiconductor film.

15. The method for manufacturing a semiconductor device according to claim 14, wherein a thickness of said second crystalline semiconductor film is greater than a thickness of said first crystalline semiconductor film.

16. The method for manufacturing a semiconductor device according to claim 15, wherein a thickness of said second crystalline semiconductor film is greater than a combined thickness of said first crystalline semiconductor film and said gate insulating film.

17. The method for manufacturing a semiconductor device according to claim 15, further comprising the step of forming a gate electrode of the thin film transistor on said gate insulating film after said step (c), wherein a thickness of said second crystalline semiconductor film is greater than a combined thickness of said first crystalline semiconductor and said gate insulating film at a region that is not covered by said gate electrode.

18. The method for manufacturing a semiconductor device according to claim 14, further comprising the step of doping an identical impurity element simultaneously into regions of said first island-shaped semiconductor layer that will become source and drain regions and a region of said second island-shaped semiconductor layer that will become an n-type region or a p-type region after said step (e).

19. The method for manufacturing a semiconductor device according to claim 14, further comprising, after said step (e), the steps of:
(f) doping a first impurity element into regions of said first island-shaped semiconductor layer that will become source and drain regions through said gate insulating film;
(g) doping an n-type impurity element into a region of said second island-shaped semiconductor layer that will become an n-type region; and
(h) doping a p-type impurity element into a region of said second island-shaped semiconductor layer that will become a p-type region.

20. The method for manufacturing a semiconductor device according to claim 19,
wherein said first impurity element includes an n-type impurity element, and
wherein said step (f) and said step (g) are conducted simultaneously.

21. The method for manufacturing a semiconductor device according to claim 19,
wherein said first impurity element includes a p-type impurity element, and
wherein said step (f) and said step (h) are conducted simultaneously.

22. The method for manufacturing a semiconductor device according to claim 19,
wherein said first island-shaped semiconductor layer is composed of a plurality of island-shaped semiconductor layers including an island-shaped semiconductor layer that will become an active region of an n-channel type thin film transistor and an island-shaped semiconductor layer that will become an active region of a p-channel type thin film transistor,
wherein said step (f) includes the steps of: (f1) doping an n-type impurity element into, of said first island-shaped semiconductor layer, the island-shaped semiconductor layer that will become the n-channel type thin film transistor through said gate insulating film, and (f2) doping a p-type impurity element into, of said first island-shaped semiconductor layer, the island-shaped semiconductor layer that will become the p-channel type thin film transistor through said gate insulating film,
wherein said step (f1) is conducted simultaneously with said step (g), and
wherein said step (f2) is conducted simultaneously with said step (h).

23. The method for manufacturing a semiconductor device according to claim 14, further comprising the step of forming a gate electrode of a thin film transistor on said gate insulating film after said step (c), wherein the step of forming said gate electrode includes the step of patterning said second crystalline semiconductor film to form the second island-shaped semiconductor layer that will become the active region of the thin film diode and at least a portion of said gate electrode simultaneously.

24. The method for manufacturing a semiconductor device according to claim 14,
wherein said substrate is a light-transmissive substrate, and
wherein the method further comprises the step of forming a light-shielding layer at a bottom of a region of said substrate on which the second island-shaped semiconductor layer that will become the active region of the thin film diode is to be formed, for blocking light entering from an opposite surface of said substrate, prior to said step (c).

25. The method of manufacturing a semiconductor device according to claim 24, wherein said step (b) includes the step of patterning said first crystalline semiconductor film to form the first island-shaped semiconductor layer that will become the active region of the thin film transistor and at least a portion of said light-shielding layer simultaneously.

26. The method of manufacturing a semiconductor device according to claim 14, wherein said step (a) comprises the steps of (a1) preparing a substrate having an amorphous semiconductor film formed thereon, and (a2) forming the first crystalline semiconductor film by irradiating said amorphous semiconductor film with laser light to crystallize said amorphous semiconductor film.

27. The method for manufacturing a semiconductor device according to claim 14, wherein said step (a) comprises the steps of: (a1) preparing a substrate having an amorphous semiconductor film formed thereon, (a2) adding a catalytic element that facilitates crystallization to said amorphous semiconductor film, and (a3) forming the second crystalline semiconductor film by conducting a heat treatment on the amorphous semiconductor film to which said catalytic element has been added to crystallize said amorphous semiconductor film.

28. The method for manufacturing a semiconductor device according to claim 14, wherein said step (d) includes the step of depositing the second crystalline semiconductor film on said gate insulating film by a plasma CVD method.

29. A semiconductor device manufactured with the manufacturing method according to claim 14.

30. A display device comprising a display region having a plurality of display sections, a frame region located in a periphery of said display region, and an optical sensor section including a thin film diode,
wherein each of said display sections has an electrode and a thin film transistor connected to said electrode,
wherein said thin film transistor and said thin film diode are formed on a single substrate,
wherein said thin film transistor includes a first crystalline semiconductor layer including a channel region, source and drain regions, a gate insulating film disposed to cover said first crystalline semiconductor layer, and a gate electrode disposed on said gate insulating film to control a conductivity of said channel region,
wherein said thin film diode includes a second crystalline semiconductor layer including at least an n-type region and a p-type region,
wherein said second crystalline semiconductor layer is formed on said gate insulating film in contact with a surface of said gate insulating film, and
wherein said n-type region or said p-type region and said source and drain regions contain an identical impurity element.

31. The display device according to claim 30,
wherein said display region further comprises a backlight and a backlight control circuit that adjusts a luminance of light emitted from said backlight, and
wherein said optical sensor section generates illuminance signals based on a brightness of external light and outputs the signals to said backlight control circuit.

32. The display device according to claim 30, further comprising a plurality of photo touch sensor sections each having said optical sensor section, wherein each of said plurality of photo touch sensor sections is disposed in said display region, and each of said photo touch sensor sections corresponds to one display section or a set of two or more display sections.
